(19) United States
(12) Patent Application Publication
(10) Pub. No.: US 2017/0169962 A1
(43) Pub. Date: Jun. 15, 2017

(54) SWITCH DEVICE, USE OF THE SWITCH DEVICE, OPERATING SYSTEM, AND OPERATING METHOD

(71) Applicant: FRAUNHOFER-GESELLSCHAFT ZUR FÖRDERUNG DER ANGEWANDTEN FORSCHUNG E.V., München (DE)

(72) Inventors: Jan Soeren EMMERICH, Solingen (DE); Michael Ten HOMPEL, Dortmund (DE)

(73) Assignee: FRAUNHOFER-GESELLSCHAFT, Munich (DE)

(21) Appl. No.: 15/120,560

(22) PCT Filed: Feb. 23, 2015
(86) PCT No.: PCT/EP2015/000408

§ 371 Date: Feb. 28, 2017

(30) Foreign Application Priority Data
Feb. 21, 2014 (DE) 10 2014 002 534.9
Feb. 24, 2014 (DE) 10 2014 002 382.6

(51) Int. Cl. H01H 9/02; H03K 17/96

(52) U.S. Cl. CPC H01H 9/0271; H03K 17/9627; H03K 17/964

(57) ABSTRACT

Switch device (1) that can be operated from an actuation side (S1), said switch device (1) comprising:
a plate-shaped main body (10),
a plate-shaped actuation part (20),
a connection device (30) located between the main body (10) and the actuation part (20) made from an elastic material,
at least one sensor (41, 42, 43, 44), which is located between the main body (10) and the actuation part (20) and viewed in the thickness direction (Z) are located at the side of the connection device (30), so that each sensor (41, 42, 43, 44) can be used to detect a position of one region, arranged on said sensor, of the second surface in the thickness direction (Z),
   and the use of the switch device (1), operating system and operating method.

The invention relates to an electrical switch device, a use of the switch device, an operating system and operating methods.

DE 20 2006 001 717 U1 discloses an electrical switch with a wobble plate arranged on a dome.

The object of the present invention is to provide an electrical switch device which is as simple as possible to construct and as simple as possible to produce, and which can be used in an efficient manner as an input device.

This object is achieved with the features of claim 1. Further embodiments are specified in the dependent claims which reference this claim.

According to the invention a switch device is in particular provided, which can be operated from an actuation side, the switch device having:
a plate-shaped main body with a connection surface which is facing the actuation side of the electrical switch device,
a plate-shaped actuation part arranged thereon, viewed in the thickness direction, with an actuation surface facing the actuation side and a connection surface located contrary to this,
a connection device made from an elastic material, which is attached to an inner area of the connection surface of the actuation part and is fixed to a second surface on an inner area of the connection surface of the main body,
at least one sensor, which is located between the main body and the actuation part and when viewed in the thickness direction is located at the side of the connection device, so that each sensor can be used to detect one position each of one region, which is located at said sensor, of the second surface in the thickness direction.

According to one embodiment of the switch device, the actuation part can have a display which is located in an inner area, viewed in the thickness direction, of the actuation interface of the actuation part.

Providing the connection device enables mounting on the main body, and also a local change in the position of an area of an actuation part relative to a sensor respectively located in this area.

The connection device which is made from elastic material enables the connection device to have a resilience.

According to one aspect a switch device is provided, which can be operated from an actuation side (S1), the switch device (1) comprising:
a plate-shaped main body (10) with a connection surface (10a), which is facing the actuation side (S1) of the electrical switch device (1),
a plate-shaped actuation part (20) arranged thereon, viewed in the thickness direction (Z), with an actuation surface facing the actuation side (S1) and a connection surface (20b) located contrary to this,
a connection device (30) having at least one connection layer (31) made from an elastic material, which is attached to an inner area (20c) of the connection surface (20b) of the actuation part (20) and is fixed to a second surface (30b) on an inner area (11) of the connection surface (10a) of the main body (10),
at least one sensor (41, 42, 43, 44), which is located between the main body (10) and the actuation part (20) and viewed in the thickness direction (Z) are located at the side of the connection device (30), so that each sensor (41, 42, 43, 44) can be used to detect a position of one region, arranged on said sensor, of the second surface in the thickness direction (Z).

According to one embodiment of the switch device, the connection device (30) consists of at least one connection layer (31).

According to a further aspect a switch device (1) is provided, which can be operated from an actuation side (S1), the switch device (1) having:
a plate-shaped main body (10) with a connection surface (10a), which is facing the actuation side (S1) of the electrical switch device (1),
a plate-shaped actuation part (20) arranged thereon, viewed in the thickness direction (Z), with an actuation surface (20a) facing the actuation side (S1) and a connection surface (20b) located contrary to this,
a connection device (30) having at least one connection layer (31) made from an elastic material, which is attached to an inner area (20c) of the connection surface (20b) of the actuation part (20) and with a second surface (30b) is fixed to an inner area (11) of the connection surface (10a) of the main body (10),
at least one sensor (41, 42, 43, 44), which are located between the main body (10) and the actuation part (20) and viewed in the thickness direction (Z) are located at the side of the connection device (30), so that each sensor (41, 42, 43, 44) can be used to detect a position of one region, arranged on said sensor, of the second surface in the thickness direction (Z).

According to one embodiment of the switch device, the connection device (30) consists of at least one connection layer (31).

According to a further aspect a switch device is provided, having:
a housing device (H) with a plate-shaped body (10) with a connection surface (10a), which is facing an actuation side (S1) of the electrical switch device (1), and with a housing part (H1),
a plate-shaped actuation part (20) arranged thereon, viewed in the thickness direction (Z), with an actuation surface (20a) facing the actuation side (S1) and a connection surface (20b) located opposite to this,
a display (80) integrated in the actuation part (20) for displaying images on the actuation side (S1), wherein the housing part (H1) comprises: a side wall (H4), which surrounds the connection device (30) and the actuation part (20) viewed in the thickness direction (Z) at least in some sections, and an edge section (H5) which adjoins to the side wall (H4) towards the actuation side (S1) and forms a central opening (H7), in which the display (80) extends, at least in some sections,
a connection device (30) having at least one connection layer (31) made from an elastic material, which is attached to an inner area (20c) of the connection surface (20b) of the actuation part (20) and is fixed with a second surface (30b) to an inner area (11) of the connection surface (10a) of the main body (10),
at least one sensor (41, 42, 43, 44), which are located between the main body (10) and the actuation part (20) and viewed in the thickness direction (Z) are located at the side of the connection device (30), so that each sensor (41, 42, 43, 44) can be used to detect a position of one region, arranged on said sensor, of the second surface in the thickness direction (Z).

This enables the connection device (30) to consist of at least one connection layer (31).

According to a further aspect a switch device is provided, having:
a housing device (H) with a plate-shaped body (10) with a connection surface (10a), which is facing an actuation side (S1) of the electrical switch device (1), and with a housing part (G1),
a plate-shaped actuation part arranged thereon, viewed in the thickness direction (Z), with an actuation surface facing an actuation side (S1) and a connection surface (20b) located opposite to this,
a display (80) integrated in the actuation part (20) for displaying images on the actuation side (S1), wherein the housing part (H1) comprises: a side wall (H4) extending away from the main body (10), which viewed in the thickness direction (Z) surrounds the actuation part (20) at least in some sections, and an edge section (H5) which adjoins to the side wall (H4) towards the actuation side (S1) and forms a central opening (H7) in which the display (80) extends, at least in some sections,
a connection device (30) having at least one connection layer (31) made from an elastic material, which is attached to an outer area of the connection surface (20b) of the actuation part (20) and with a second surface (30b) is fixed to an outer area of the connection surface (10a) of the main body (10),
at least one sensor (41, 42, 43, 44), which are located between the main body (10) and the actuation part (20) and are located at the side of the connection device (30) viewed in the thickness direction (Z), so that each sensor (41, 42, 43, 44) can be used to detect a position of one region, arranged on said sensor, of the second surface in the thickness direction (Z).

This enables the connection device (30) to consist of at least one connection layer (31).

According to a further aspect a switch device is provided, having:
a plate-shaped main body (10) with a connection surface (10a), which is facing the actuation side (S1) of the electrical switch device (1),
a plate-shaped actuation part (20) arranged thereon, viewed in the thickness direction (Z), with an actuation surface (20a) facing an actuation side (S1) and a connection surface (20b) located opposite to this,
a display (80) integrated in the actuation part (20) for displaying images on the actuation side (S1), wherein the housing part (H1) comprises: a side wall (H4) extending away from the main body (10), which viewed in the thickness direction (Z) surrounds the actuation part (20) at least in some sections, and an edge section (H5) which adjoins to the side wall (H4) towards the actuation side (S1), which is connected to the actuation part (20) along its circumference at least in a section and which forms a central opening (H7) in which the display (80) extends, at least in a section,
at least one sensor (41, 42, 43, 44), which is located between the main body (10) and the actuation part (20) and is located at the side of the connection device (30) viewed in the thickness direction (Z), so that each sensor (41, 42, 43, 44) can be used to detect a position of one region, arranged on said sensor, of the second surface in the thickness direction (Z).

According to one embodiment of the switch device it is provided,
that the actuation part (20) has a display (80), which is located in an inner area (20e) of the actuation surface (20a) of the actuation part (20), viewed in the thickness direction (Z).
that the internal display area (20e) is designed as a recess formed on the actuation surface (20a) and the display (80), viewed in the thickness direction (Z), is located at least partially in the recess.

According to one embodiment of the switch device it is provided that the actuation part (20) is optically transparent, at least in portions of its area, and wherein the main body (10) has an internal display area (10e) viewed in the thickness direction (Z), in which the display (80) is arranged, the position of the internal display area (10e) being defined according to one of the following alternatives:
the display area (20e) viewed in the thickness direction (Z) is situated within an area defined by the sensors (41, 42, 43, 44) or between sensors (41, 42, 43, 44) and outside of the at least one connection layer (31) viewed in the thickness direction (Z),
the display area (20e) viewed in the thickness direction (Z) is situated within an area defined by the sensors (41, 42, 43, 44) or between sensors (41, 42, 43, 44) and viewed in the thickness direction (Z), at least partially inside at least one of the at least one connection layers (31), wherein the at least one connection layer, which is located within the display area (20e), is optically transparent.

According to one embodiment of the switch device, it is provided that the internal display area (20e) is designed as a recess formed on the connection surface (20a) and the display (80), viewed in the thickness direction (Z), is located at least partially in the recess.

According to one embodiment of the switch device, the plate-shaped actuation part (20) is designed as a rigid part.

According to one embodiment of the switch device, the plate-shaped actuation part (20) is designed as a flexible elastic part.

According to one embodiment of the switch device, the switch device (1) comprises two sensors (41, 42, 43, 44), two of which are in each case arranged opposite each other in relation to the area centroid (FS) of the actuation interface (20a).

According to one embodiment of the switch device, the at least one sensor (41, 42, 43, 44) is designed in such a way that each of these detects, in a contactless manner, the distance from the same to the point of the connection surface (20b) of the actuation part part (20) opposite thereto.

According to one embodiment of the switch device, the at least one sensor (41, 42, 43, 44) is designed as an optical sensor.

According to one embodiment of the switch device, the at least one sensor (41, 42, 43, 44) is designed as an inductive sensor.

According to one embodiment of the switch device, the at least one sensor (41, 42, 43, 44) is designed in the form of a mechanical sensor with a switch component.

According to one embodiment of the switch device, the switch device comprises a link (e.g. via WLAN) to a data network.

According to one embodiment of the switch device it is provided that, after evaluation of the inputs made via the sensors (41 to 44), input-related data content (e.g. in the form of apps) can be downloaded over the data network link from a central database and can be displayed on the display 80.

According to a further aspect, an embodiment of the switch device can be used as a device for inputting logistical data in a storage area.

According to a further aspect, an embodiment of the switch device can be used as a device for inputting logistical data and outputting logistical data, in each case in a storage area.

A further aspect relates to the use of one embodiment of the switch device with a display as an interactive human-machine interface in the field of logistics and other industrial applications, particularly in warehouse management and other material flow systems,
wherein a number of task-related alternatives can be displayed on the display,
wherein via a user's input, which acts on sensors (41 to 44), a selection is made from the displayed alternatives, whereupon the next action, or the next selection to be made, is displayed from the central database via the WLAN link.

According to a further aspect, the use of an embodiment of the switch device with a display is provided, for the menu-guided selection of a task in the area of warehouse logistics and other industrial applications,
wherein apps are held available in the central database for a multiplicity of tasks, which present on the display via the network link reproducible sequences of actions, alternatives to the task-related selection and/or to necessary inputs of information,
wherein the user selects the app appropriate to the task pending and then processes this interactively using the input devices via the sensors 41 to 44 and in observance of the representations on the display (80).

According to a further aspect, the switch device can be used with input means and a display for the menu-guided selection of a task in an operating system (S), and in particular in a warehouse system or a production plant or other industrial applications, wherein application functions (apps) are held available in a central database for a multiplicity of tasks, which present on the display (80) via a network link sequences of actions, alternatives to the task-related selection and/or to necessary inputs of information that can be reproduced, wherein the user selects the application function (app) appropriate to the pending task and processes this interactively using the input devices via the sensors 41 to 44 and in observance of the representations on the display (80).

According to a further aspect, an operating system is provided having at least one embodiment of the switch device, a central system and a plurality of work-area participants, wherein the switch device (1) comprises an output interface (93), via which, due to the provision of at least one control field, task execution commands can be generated and optionally submitted by means of a menu control module (96)
to the central system (Z),
to all of the plurality of work-area participants (T),
individual participants from the plurality of work-area participants (T).

According to one aspect an operating method is provided, having a mobile switch device (1) which is designed as a hand-held device and comprises input means and a display for the menu-driven selection and execution of a task in an industrial operating system (S):
provision of a multiplicity of task-application functions (apps) in a central database,
the display via a network link of reproducible action sequences of participant tasks and/or alternatives to the task-related selection and/or to the necessary inputs of information on the display (80) of the switch device (1),
selection by a user of application functions (apps) appropriate to the pending task,
processing of these tasks interactively using the input means and in observance of the representations on the display (80).

According to one embodiment of the operating method, it is provided that in the selected application function (app) at least one participant task to be executed by one or more participants (T; T1, T2, T3) of the operating system (S) can be selected on the display (80),

that after selection of a participant task a selected participant task is submitted by activation of the switch device (1) to multiple participants (T; T1, T2, T3),

that among each of the participants (T; T1, T2, T3) a prioritization of the participant tasks received over a pre-defined work period takes place, by means of task execution commands,

that a consistency check and a reconciliation of the participant tasks is effected between the participants (T; T1, T2, T3), in such a way as to avoid the highest priority being assigned to the same task,

that the task with top priority is in each case processed by the respective participant (T; T1, T2, T3), so that each participant (T; T1, T2, T3) executes a top priority task.

In this case it can be provided in particular that the industrial operating system (S) is a warehouse system, and wherein at least two participants (T; T1, T2, T3) are warehouse operating devices.

According to one embodiment of the operating method, control fields are provided via an output interface (93) of the switch device (1) in menu formats that are selectable by actuating the switch device (1), and by means of a menu control module (96), task execution commands are generated and optionally submitted
to the central system (Z),
to all of the plurality of work-area participants (T),
individual participants from the plurality of work-area participants (T).

According to one embodiment of the operating method it is provided that the switch device (1) is designed according to an embodiment described herein.

The expression “along” in connection with the direction specifications given herein, which may relate to the profile of a contour line or a surface or which may relate to a direction of a mechanical component such as an axle or shaft, may mean in particular that the tangent to the respective contour line or to the respective surface in its trajectory in accordance with the direction specification, or longitudinal extension and e.g. the central axis of the mechanical component, locally deviates by a maximum angle of 45 degrees and preferably by a maximum of 30 degrees from a reference direction or reference axis, to which the respective direction specification is related.

The expression “transverse” in connection with the direction specifications given herein, which may relate to the profile of a contour line or a surface or which may relate to a direction of a mechanical component such as an axle or shaft, may mean in particular that the tangent to the respective contour line or to the respective surface in its trajectory in accordance with the direction specification, or longitudinal extension and e.g. the central axis of the mechanical component, locally deviates by a minimum angle of 45 degrees and preferably by a minimum of 30 degrees from a reference direction or reference axis, to which the respective direction specification is related.

The expression “viewed in the thickness direction Z” used herein for the purpose of designating a relative position of features or components being addressed, means a viewing direction, by reference to which a position of the features or components addressed is specified.

According to one aspect of the invention, a use of the switch device is provided as a device for inputting logistical data throughout the entire field of logistics and industrial applications, for instance in a warehouse area or in production.

According to a further aspect of the invention, a use of the switch device in the design having a display is provided as a device for inputting logistics data and outputting logistical data throughout the entire field of logistics and industrial applications, for instance either in a storage area or in production.

According to one variant of the invention, a use of switch devices according to the prior art in a design having a display is provided as a device for inputting logistics data and outputting logistical data throughout the entire field of logistics and industrial applications, for instance either in a storage area or in production.

Hereafter embodiments of the invention are described by reference to the enclosed drawings, that show:

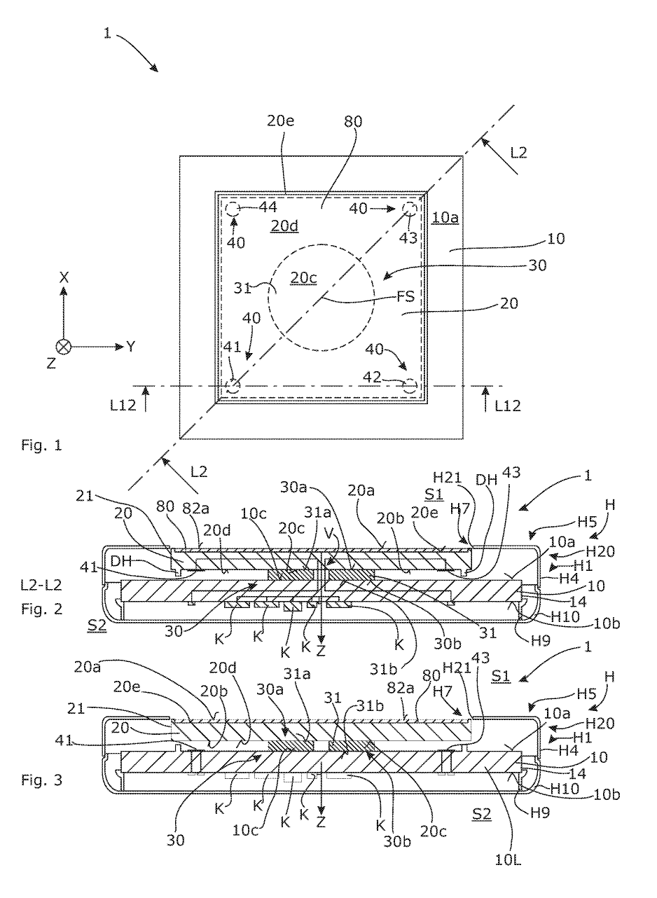

FIG. 1 a plan view of an embodiment of the electrical switch device with a housing, a main body arranged therein, an actuation part and a connection device located between these, as well as sensors, wherein the sensors are shown dashed as hidden parts in the plan view,

FIG. 2 a sectional view of the embodiment of the electrical switch device according to FIG. 1 along the line L2-L2 drawn in FIG. 1, wherein contactless sensors in the form of optical sensors are used,

FIG. 3 a sectional view of the embodiment of the electrical switch device according to FIG. 1 along the line L2-L2 drawn in FIG. 1, wherein contactless sensors in the form of inductive sensors are used,

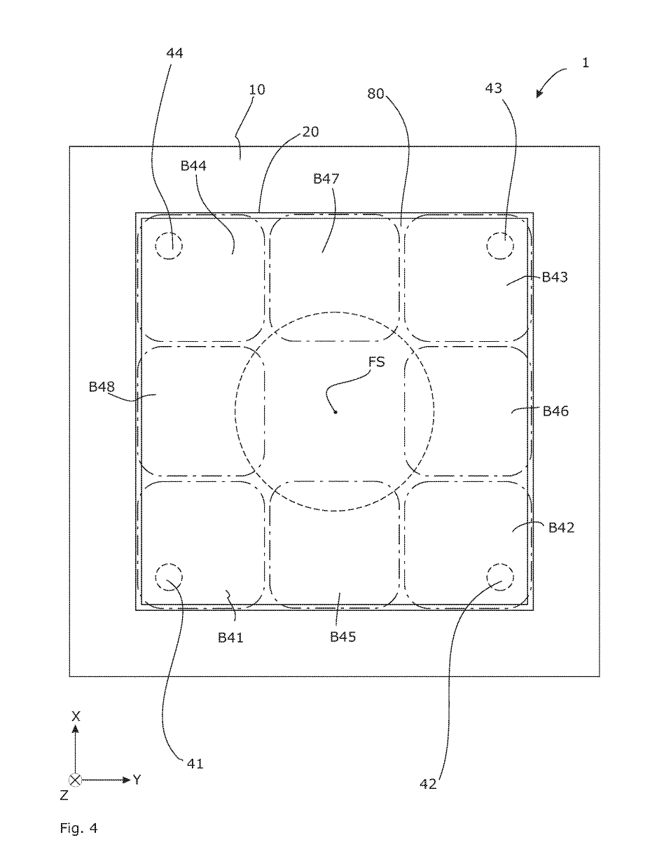

FIG. 4 another plan view of the embodiment of the electrical switch device according to FIG. 1, in which areas of the actuation part are shown dashed,

FIG. 5 as a first step of a sequence of steps the sectional view of the embodiment of the electrical switch device according to FIG. 1 along the line L2-L2 drawn in FIG. 1, wherein the switch device is shown in a starting position,

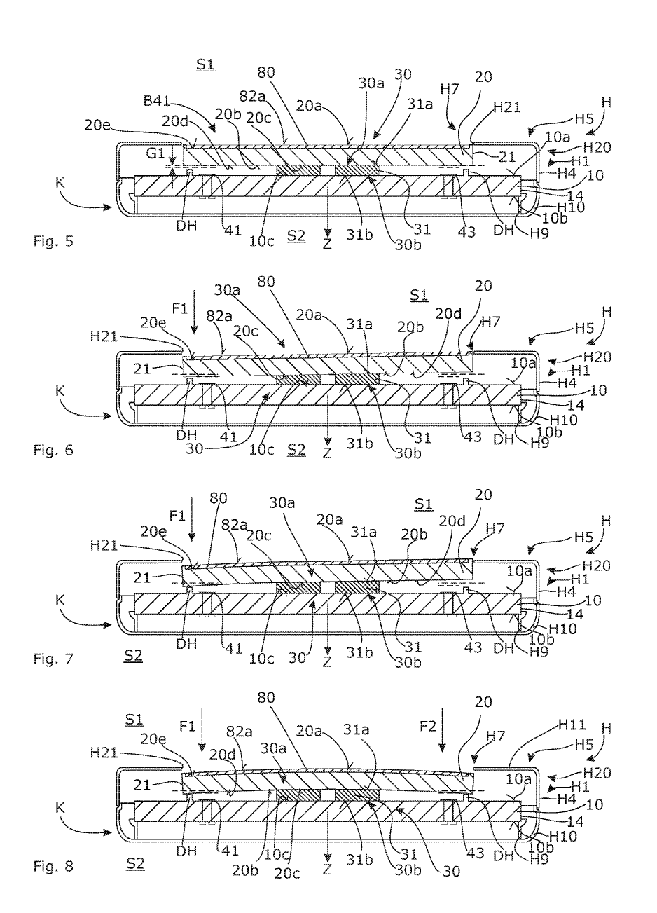

FIG. 6 the embodiment of the electrical switch device according to FIG. 1 in the representation of FIG. 5, wherein the switch device is shown in an actuation position, in which an external compressive force is exerted on a first lateral edge section of the actuation part from an actuation side,

FIG. 7 the embodiment of the electrical switch device according to FIG. 1 in the representation of FIG. 5, wherein a greater external compressive force is exerted in comparison to that of FIG. 6,

FIG. 8 the embodiment of the electrical switch device according to FIG. 1 in the representation of FIG. 5, wherein compared to FIG. 7 a further external compressive force is exerted on a second lateral edge section of the actuation part which is situated opposite to the first lateral edge section,

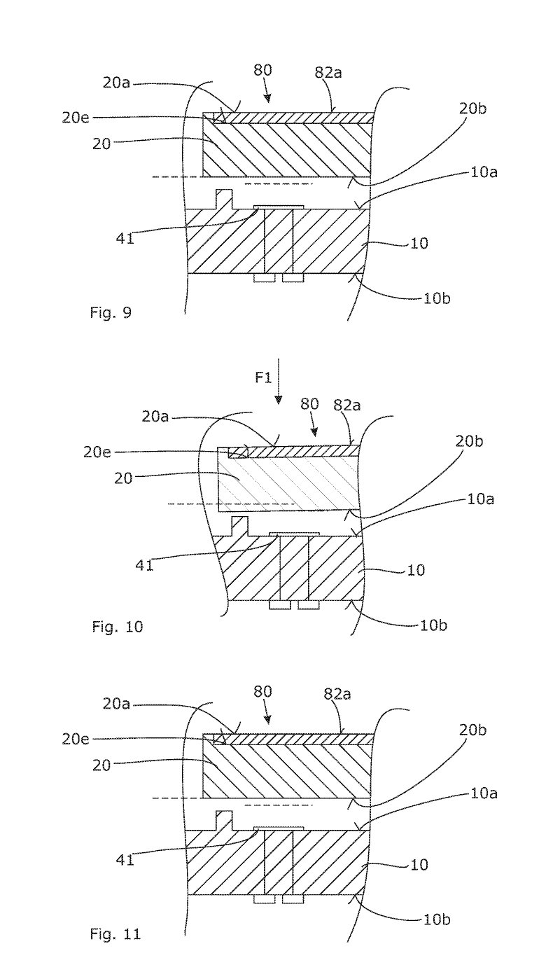

FIG. 9 a detailed view of the embodiment of the electrical switch device according to FIG. 1 with the first lateral edge section of the actuation part, wherein the switch device is in the output state shown in FIG. 5,

FIG. 10 the detailed representation of FIG. 9, wherein the switch device is in the actuation state shown in FIG. 6,

FIG. 11 the detailed representation of FIG. 9, wherein the switch device is in the actuation state shown in FIG. 7,

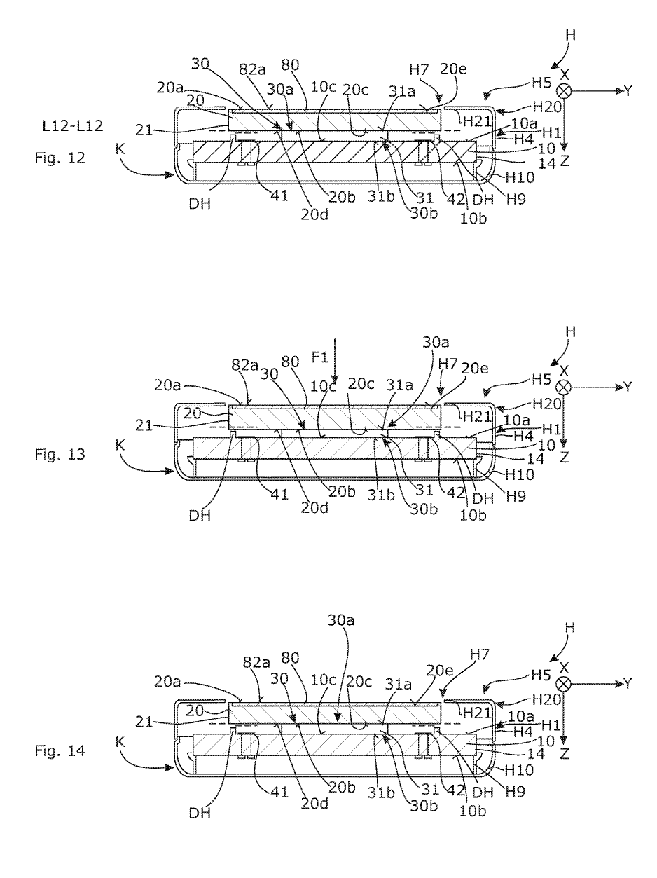

FIG. 12 as a first step of a sequence of steps, the sectional view of the embodiment of the electrical switch device according to FIG. 1 along the line L12-L12 drawn in FIG. 1, wherein the switch device is shown in a starting position,

FIG. 13 the sectional view of the embodiment of the electrical switch device according to FIG. 1 as shown in FIG. 12, wherein the switch device is shown in an actuation position,

FIG. 14 the sectional view of the embodiment of the electrical switch device according to FIG. 1 as shown in FIG. 12, wherein the switch device is shown in a further actuation position compared to that of FIG. 13,

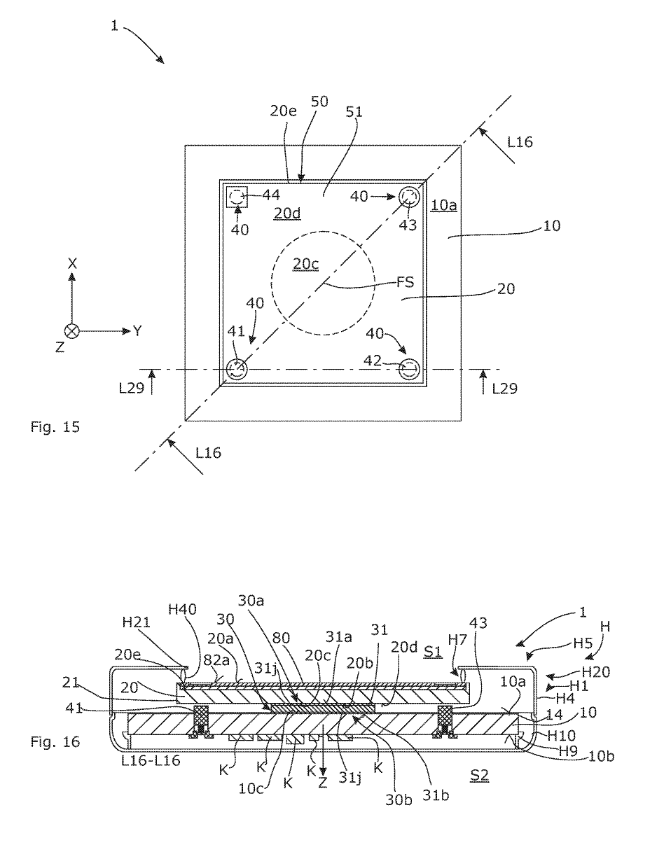

FIG. 15 a plan view of a further embodiment of the electrical switch device, wherein the sensors are shown dashed as hidden parts in the plan view,

FIG. 16 a sectional view of the embodiment of the electrical switch device according to FIG. 15 along the line L16-L16 drawn in FIG. 15,

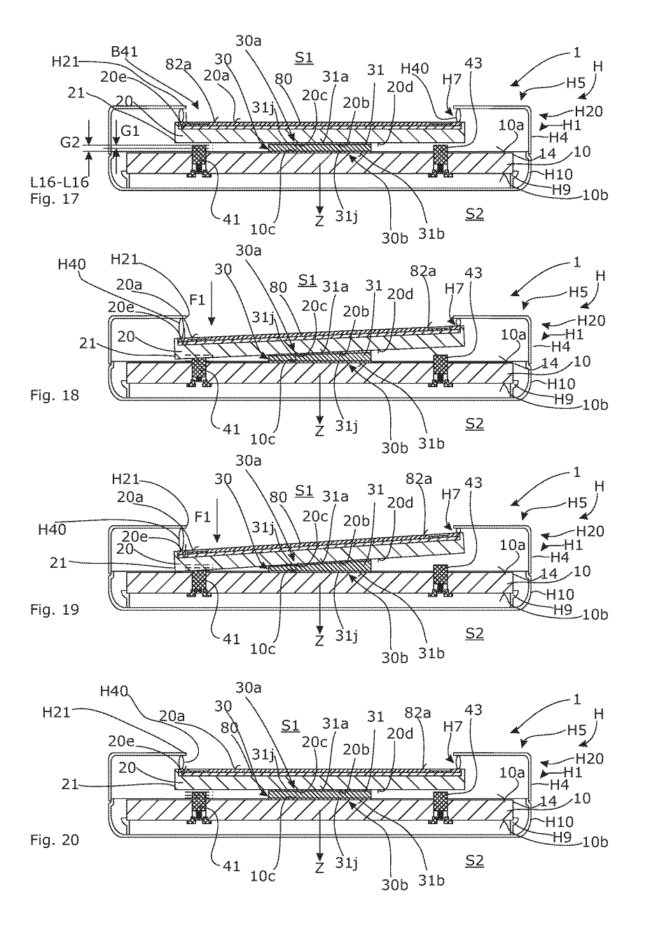

FIG. 17 as a first step of a sequence of four steps, the sectional view of the embodiment of the electrical switch device according to FIG. 15 along the line L16-L16 drawn in FIG. 15, wherein the switch device is shown in a starting position and the embodiment of the switch device shown has a flexible actuation part,

FIG. 18 the embodiment of the electrical switch device according to FIG. 15 in the representation of FIG. 17, wherein the switch device is shown in an actuation position, in which an external compressive force is exerted on a first lateral edge section of the actuation part from an actuation side,

FIG. 19 the embodiment of the electrical switch device according to FIG. 1 in the representation of FIG. 17, wherein a greater external compressive force is exerted in comparison to that of FIG. 18,

FIG. 20 the embodiment of the electrical switch device according to FIG. 1 in the representation of FIG. 17, compared to FIG. 19 a further external compressive force is exerted on a second lateral edge section of the actuation part, which is situated opposite to the first lateral edge section,

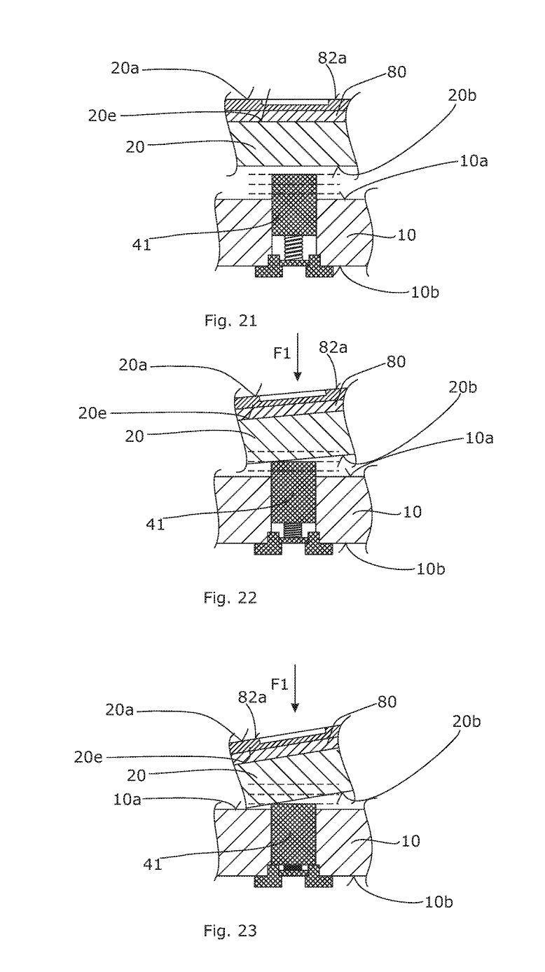

FIG. 21 a detailed view of the embodiment of the electrical switch device according to FIG. 14 with the first lateral edge section of the actuation part, wherein the switch device is in the output state shown in FIG. 16,

FIG. 22 the detailed representation of FIG. 20, wherein the switch device is in the actuation state shown in FIG. 17,

FIG. 23 the detailed representation of FIG. 20, wherein the switch device is in the actuation state shown in FIG. 18,

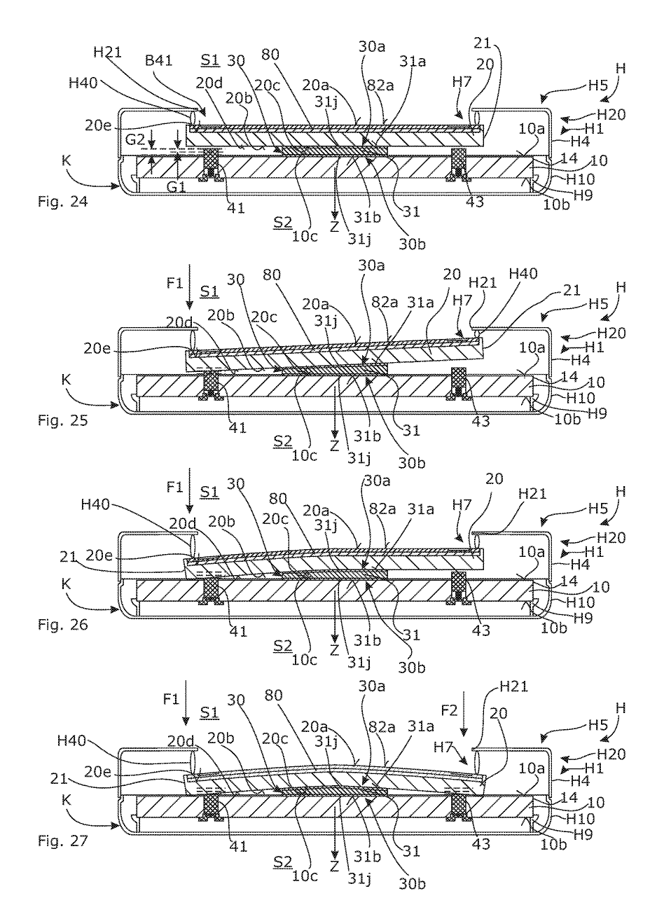

FIG. 24 as a first step of a sequence of five steps, the sectional view of the embodiment of the electrical switch device according to FIG. 15 along the line L16-L16 drawn in FIG. 15, wherein the switch device is shown in a starting position and the embodiment of the switch device shown has a rigid actuation part,

FIG. 25 the embodiment of the electrical switch device according to FIG. 15 in the representation of FIG. 24, wherein the switch device is shown in an actuation position, in which an external compressive force is exerted on a first lateral edge section of the actuation part from an actuation side,

FIG. 26 the embodiment of the electrical switch device according to FIG. 15 in the representation of FIG. 24, wherein a greater external compressive force is exerted in comparison to that of FIG. 25,

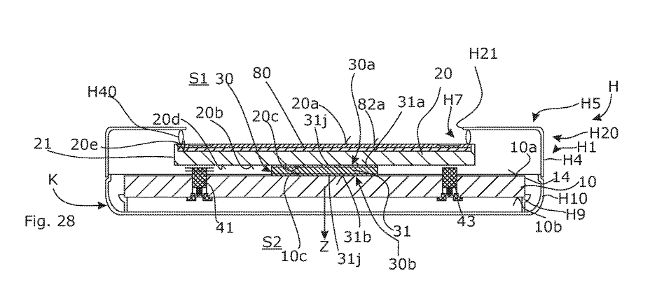

FIG. 27 the embodiment of the electrical switch device according to FIG. 15 in the representation of FIG. 24, wherein compared to FIG. 25 a further external compressive force is exerted on a second lateral edge section of the actuation part, which is situated opposite to the first lateral edge section,

FIG. 28 the embodiment of the electrical switch device according to FIG. 15 in the representation of FIG. 24, wherein compared to FIG. 27 in a further operating state no external pressure force is exerted on a lateral edge section of the actuation part,

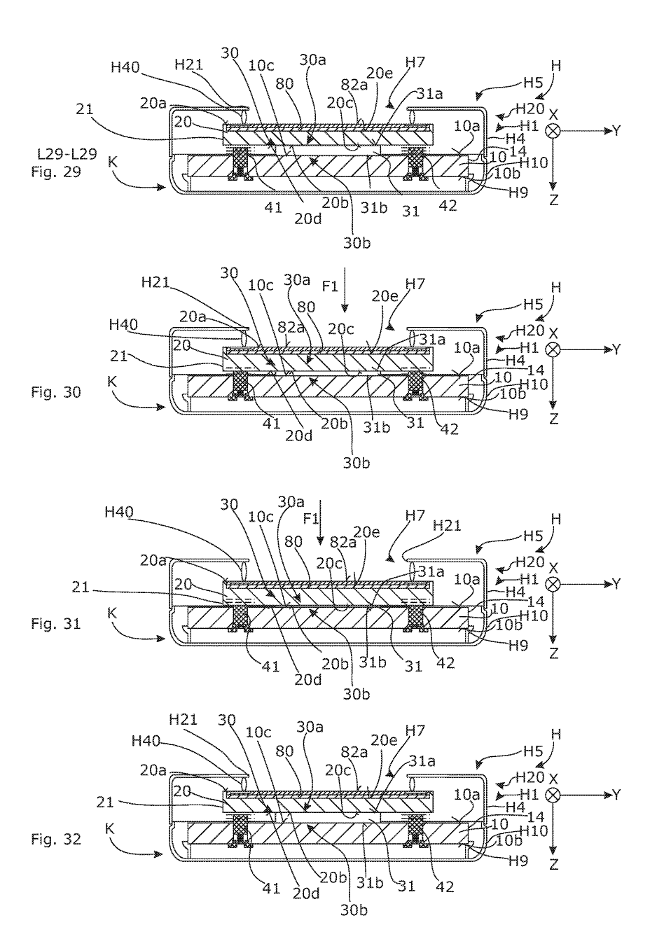

FIG. 29 as a first step of a sequence of four steps, a sectional view of the embodiment of the electrical switch device according to FIG. 15 along the line L29-L29 drawn in FIG. 15, wherein the switch device is shown in a starting position and the embodiment of the switch device shown has a rigid actuation part,

FIG. 30 the embodiment of the electrical switch device according to FIG. 15 in the representation of FIG. 29, wherein the switch device is shown in an actuation position, in which external compressive forces are exerted from an actuation side on lateral edge sections of the actuation part which are located opposite to each other,

FIG. 31 the embodiment of the electrical switch device according to FIG. 15 in the representation of FIG. 29, wherein a greater external compressive force is exerted in comparison to that of FIG. 25,

FIG. 32 the embodiment of the electrical switch device according to FIG. 14 in the representation of FIG. 29, wherein in a further operating state compared to FIG. 31 no external pressure force is again exerted on a lateral edge section of the actuation part,

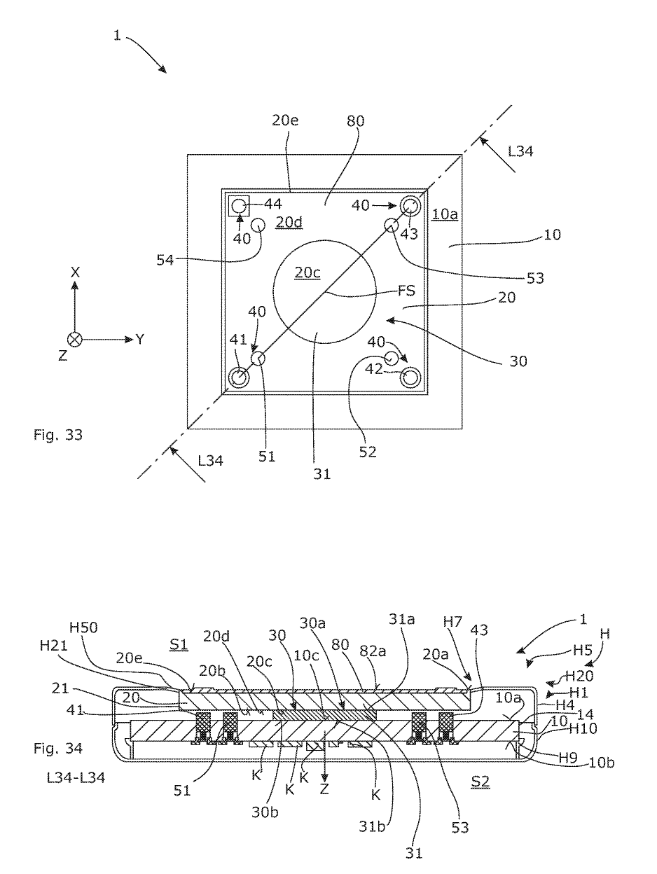

FIG. 33 a plan view of a further embodiment of the electrical switch device, wherein the sensors are shown dashed as hidden parts in the plan view,

FIG. 34 a sectional view of the embodiment of the electrical switch device according to FIG. 33 along the line L34-L34 drawn in FIG. 33,

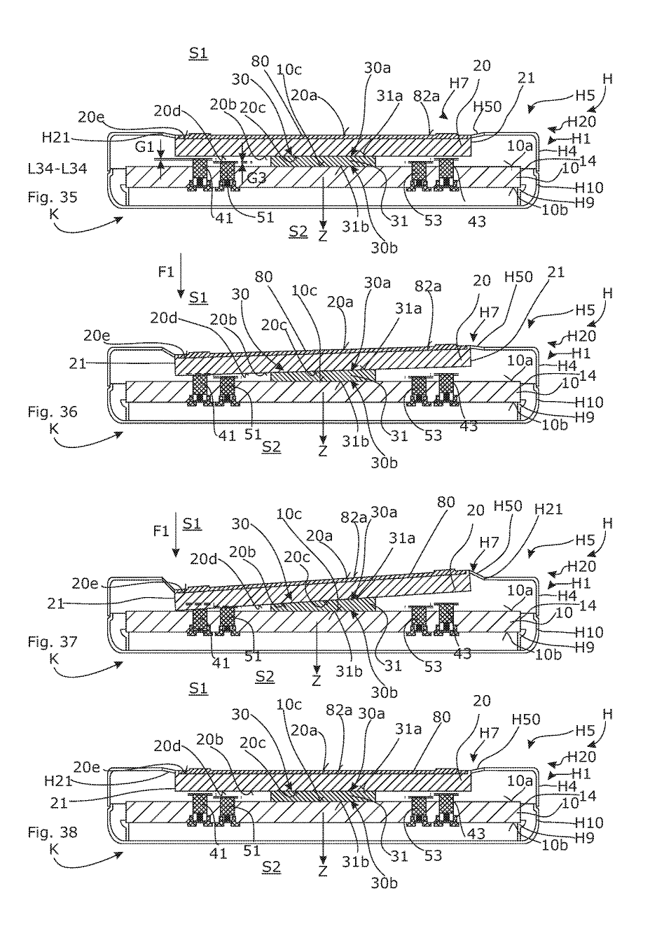

FIG. 35 as a first step of a sequence of four steps, the sectional view of the embodiment of the electrical switch device according to FIG. 33 along the line L34-L34 drawn in FIG. 33, wherein the switch device is shown in a starting position and the embodiment of the switch device shown has a rigid actuation part,

FIG. 36 the embodiment of the electrical switch device according to FIG. 33 in the representation of FIG. 35, wherein the switch device is shown in an actuation position, in which an external compressive force is exerted on a first lateral edge section of the actuation part from an actuation side,

FIG. 37 the embodiment of the electrical switch device according to FIG. 33 in the representation of FIG. 35, wherein a greater external compressive force is exerted in comparison to that of FIG. 36,

FIG. 38 the embodiment of the electrical switch device according to FIG. 33 in the representation of FIG. 35, wherein compared to FIG. 37 no external compressive force is exerted on lateral edge sections of the actuation part,

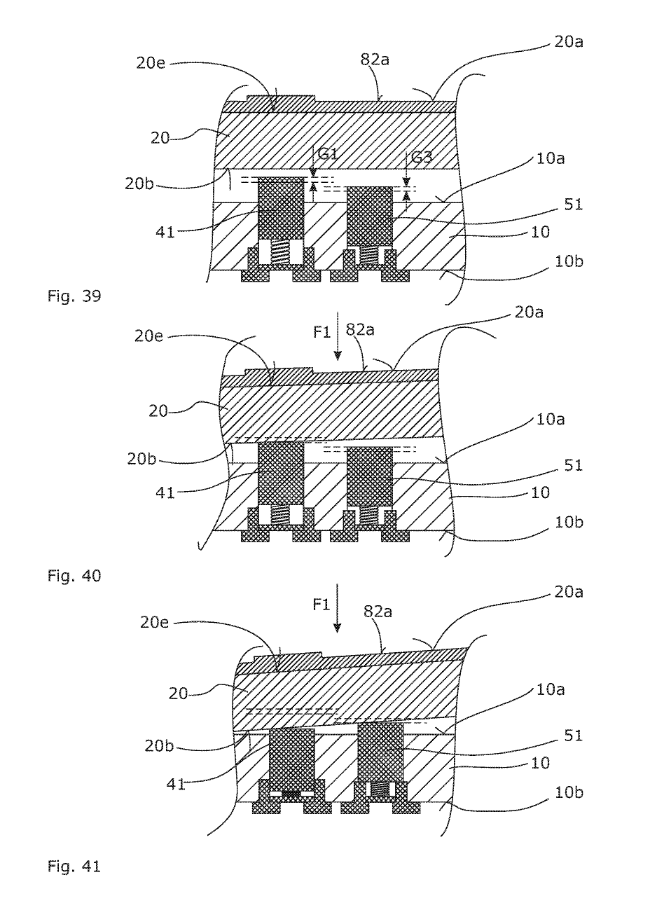

FIG. 39 a detailed view of the embodiment of the electrical switch device according to FIG. 34 with the first lateral edge section of the actuation part, wherein the switch device is in the output state shown in FIG. 34,

FIG. 40 the detailed representation of FIG. 35, wherein the switch device is in the actuation state shown in FIG. 35,

FIG. 41 the detailed representation of FIG. 36, wherein the switch device is in the actuation state shown in FIG. 36,

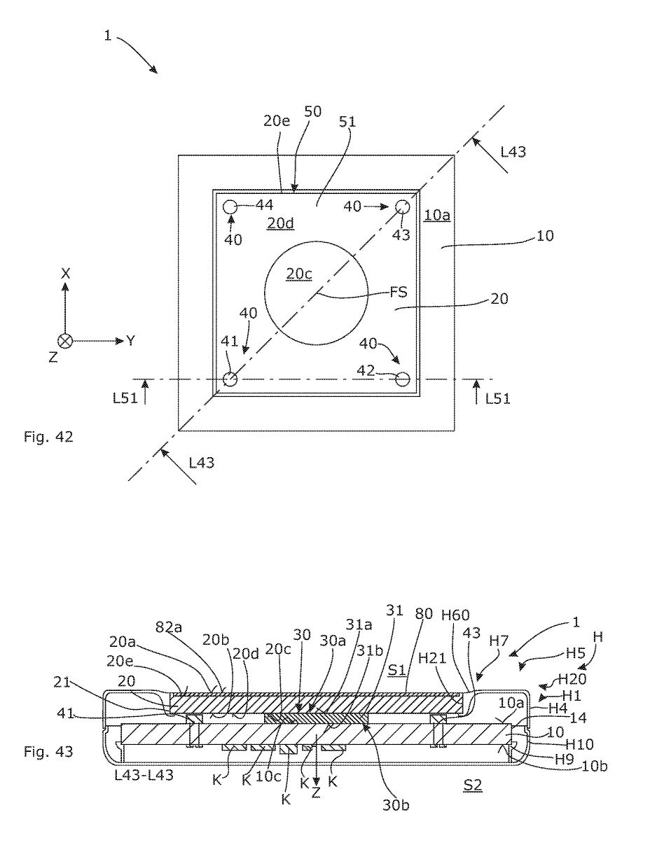

FIG. 42 a plan view of a further embodiment of the electrical switch device, wherein the sensors are shown dashed as they are hidden parts in the plan view,

FIG. 43 a sectional view of the embodiment of the electrical switch device according to FIG. 42 along the line L43-L43 drawn in FIG. 42,

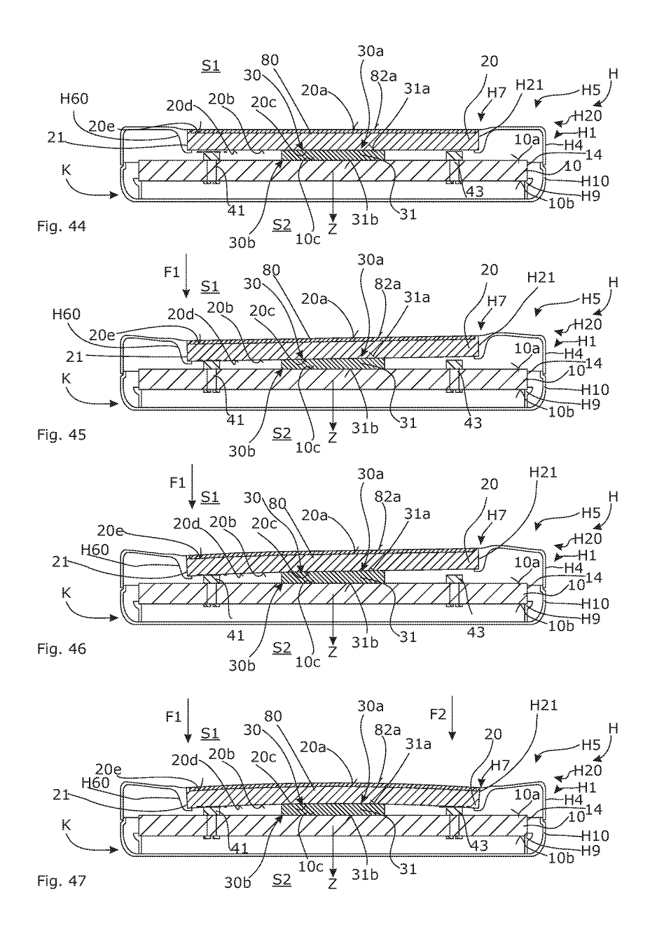

FIG. 44 as a first step of a sequence of four steps, the sectional view of the embodiment of the electrical switch device according to FIG. 42 along the line L43-L43 drawn in FIG. 42, wherein the switch device is shown in a starting position,

FIG. 45 the embodiment of the electrical switch device according to FIG. 42 in the representation of FIG. 44, wherein the switch device is shown in an actuation position, in which an external compressive force is exerted on a first lateral edge section of the actuation part from an actuation side,

FIG. 46 the embodiment of the electrical switch device according to FIG. 42 in the representation of FIG. 44, wherein a greater external compressive force is exerted in comparison to that of FIG. 45,

FIG. 47 the embodiment of the electrical switch device according to FIG. 42 in the representation of FIG. 44, compared to FIG. 46 a further external compressive force is exerted on a second lateral edge section of the actuation part which is situated opposite to the first lateral edge section,

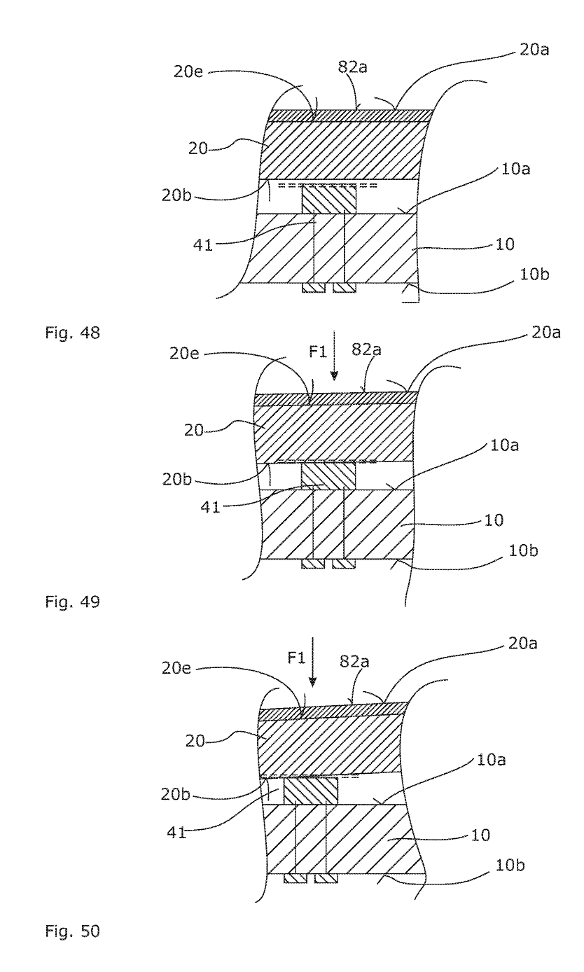

FIG. 48 a detailed view of the embodiment of the electrical switch device according to FIG. 42 with the first lateral edge section of the actuation part, wherein the switch device is in the output state shown in FIG. 44,

FIG. 49 the detailed representation of FIG. 45, wherein the switch device is in the actuation state shown in FIG. 45,

FIG. 50 the detailed representation of FIG. 46, wherein the switch device is in the actuation state shown in FIG. 46,

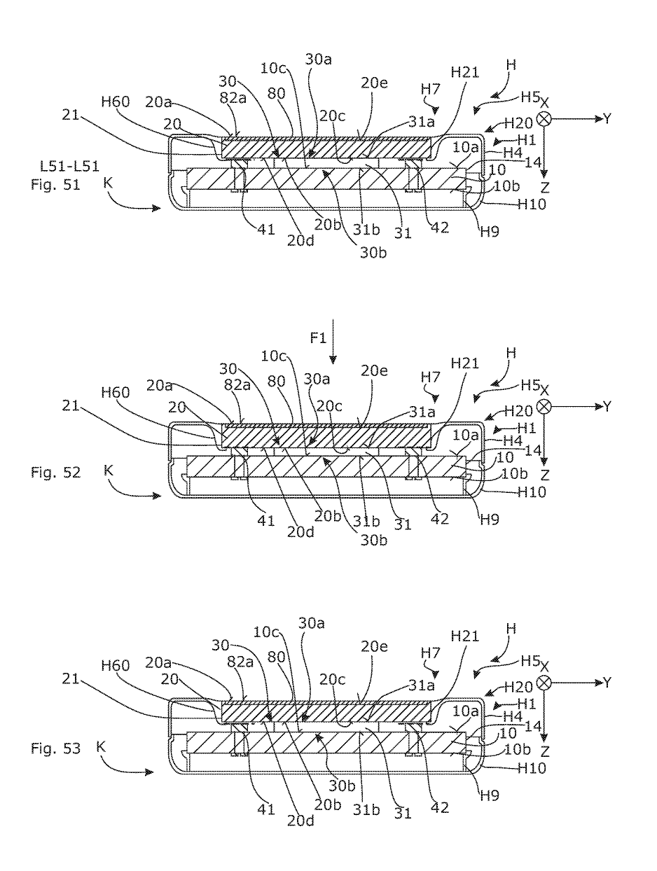

FIG. 51 as a first step of a sequence of three steps, a sectional view of the embodiment of the electrical switch device according to FIG. 42 along the line L51-L51 drawn in FIG. 42, wherein the switch device is shown in a starting position,

FIG. 52 the sectional view of the embodiment of the electrical switch device according to FIG. 42 as shown in FIG. 42, wherein the switch device is shown in an actuation position,

FIG. 53 the sectional view of the embodiment of the electrical switch device according to FIG. 42 as shown in FIG. 42, wherein the switch device is shown in a later actuation position compared to that of FIG. 52,

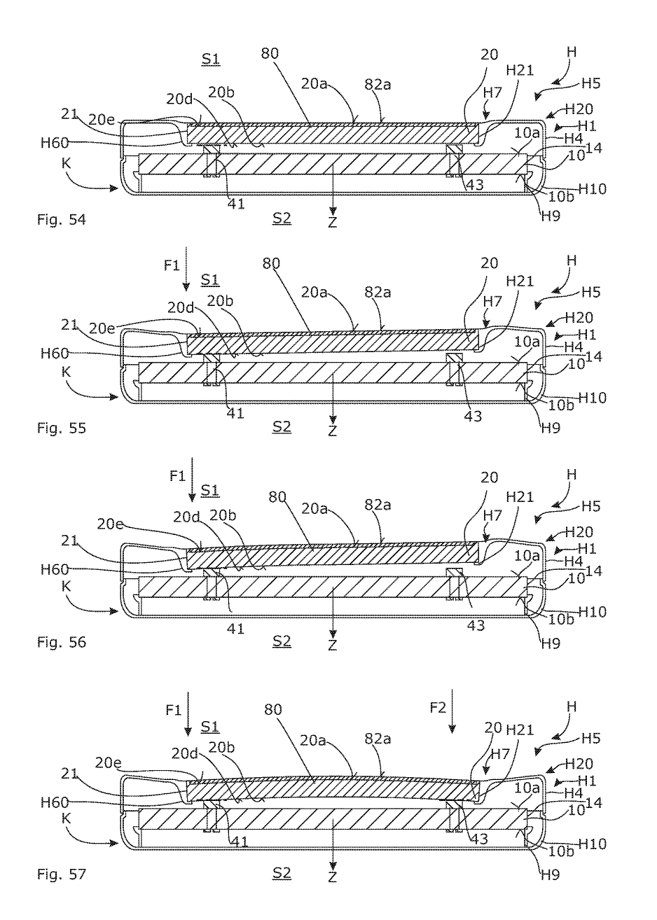

FIGS. 54 to 57 representations of operating states of a further embodiment of the electrical switch device, wherein the switch device has no connection layer and a circumferential edge section of the housing part is connected to the actuation part, wherein the operating states are analogous to the operating states shown in FIGS. 44 to 47,

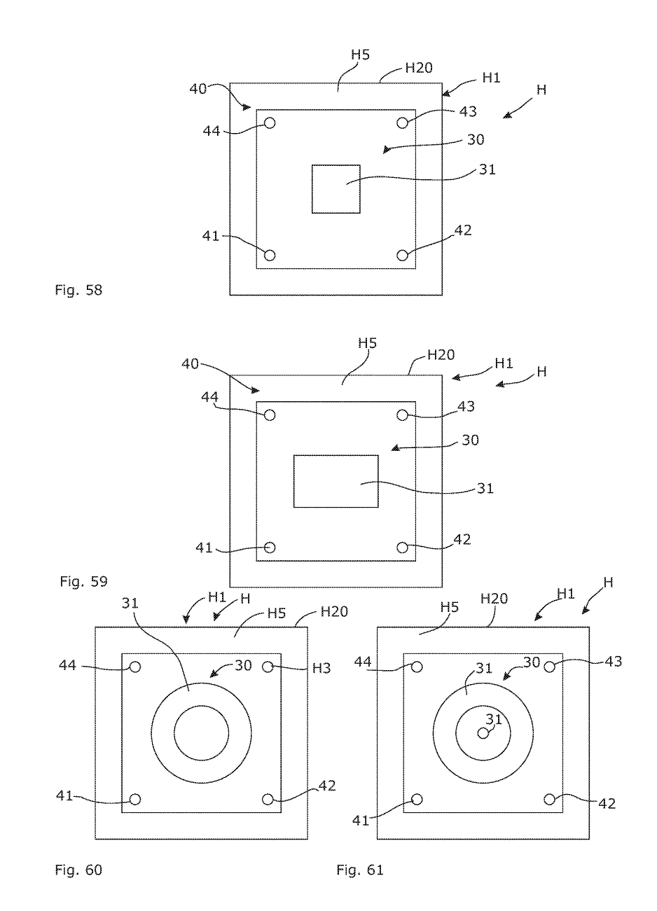

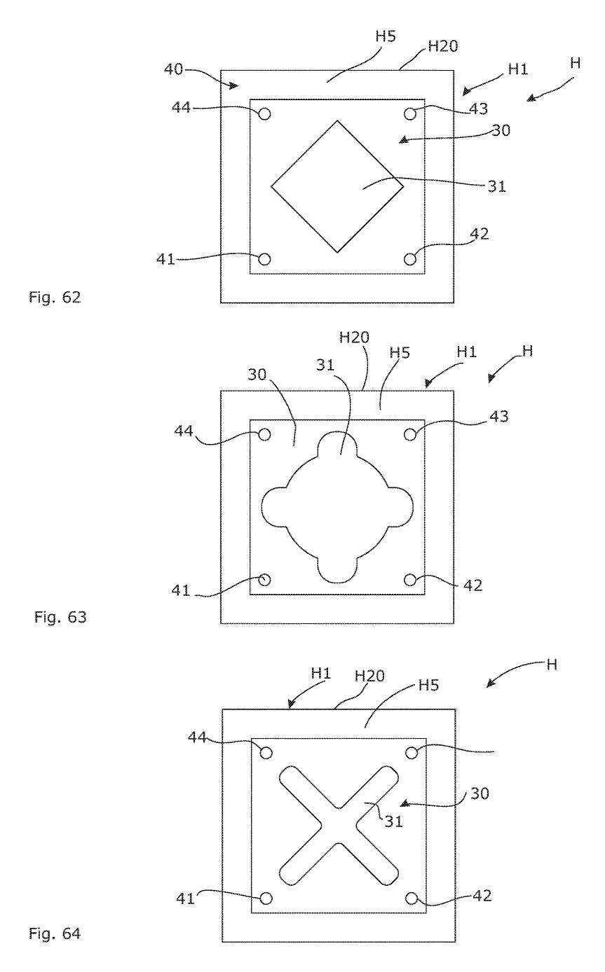

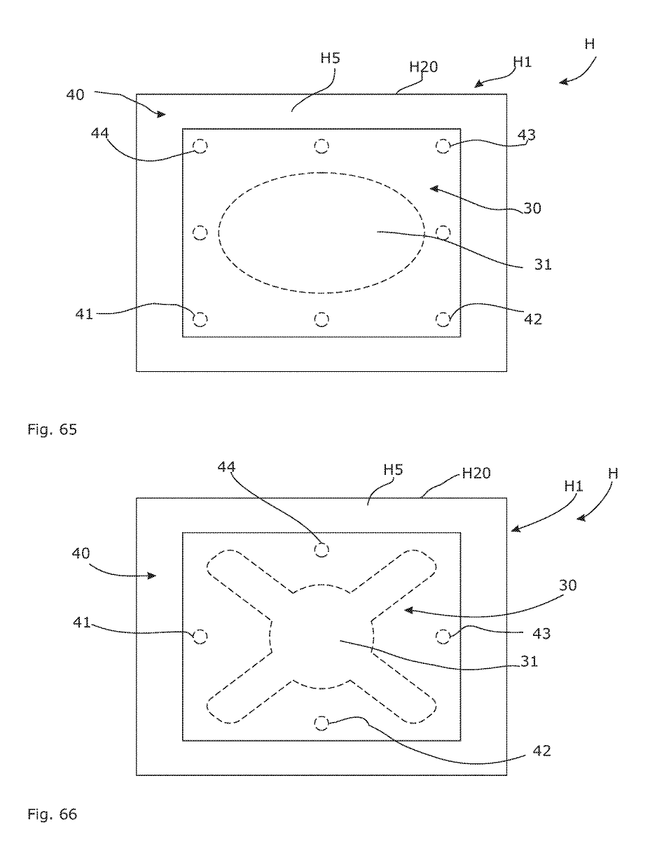

FIGS. 58 to 66 representations of various embodiments of the connection device,

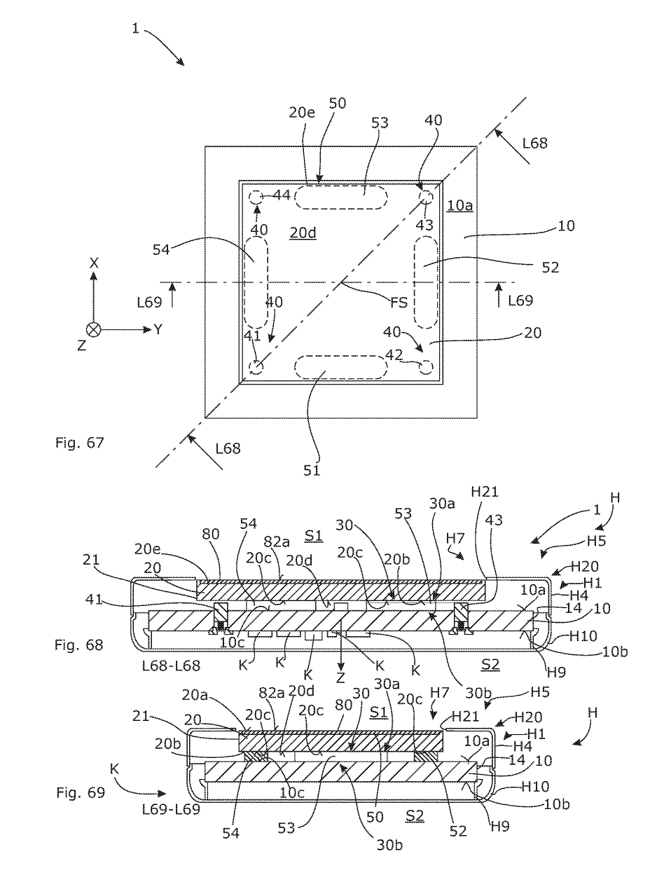

FIG. 67 a plan view of a further embodiment of the electrical switch device, wherein the sensors are shown dashed as hidden parts in the plan view,

FIG. 68 a sectional view of the embodiment of the electrical switch device according to FIG. 67 along the line L68-L68 drawn in FIG. 67,

FIG. 69 a sectional view of the embodiment of the electrical switch device according to FIG. 67 along the line L69-L69 drawn in FIG. 67,

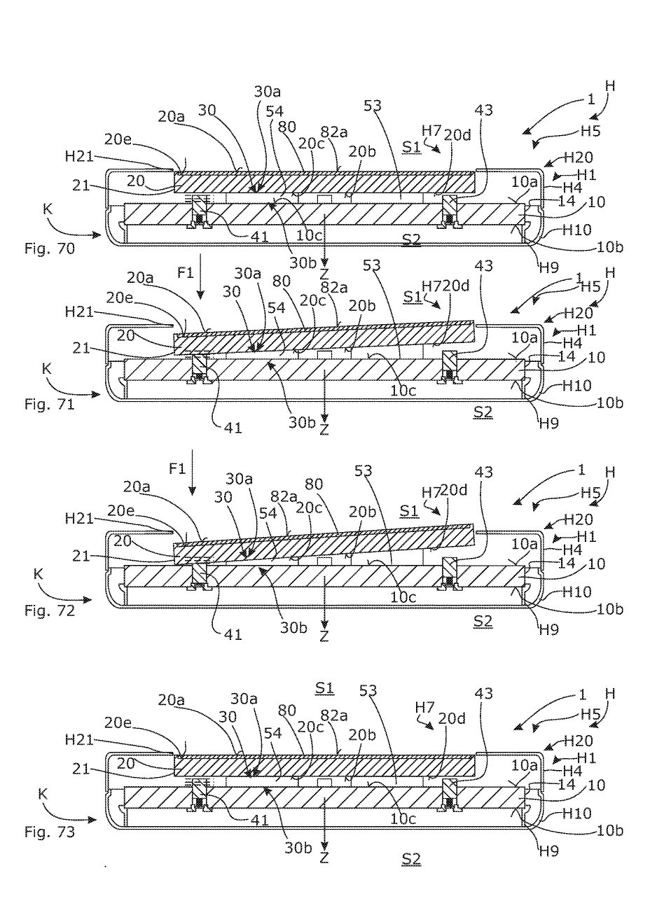

FIG. 70 as a first step of a sequence of four steps, and in an embodiment with a rigid actuation part, the sectional view of the embodiment of the electrical switch device according to FIG. 67 along the line L68-L68 drawn in FIG. 67, wherein the switch device is shown in a starting position,

FIG. 71 the embodiment of the electrical switch device according to FIG. 67 in the representation of FIG. 67, wherein the switch device is shown in an actuation position, in which an external compressive force is exerted on a first lateral edge section of the actuation part from an actuation side,

FIG. 72 the embodiment of the electrical switch device according to FIG. 42 in the representation of FIG. 67, wherein a greater external compressive force is exerted in comparison to that of FIG. 45,

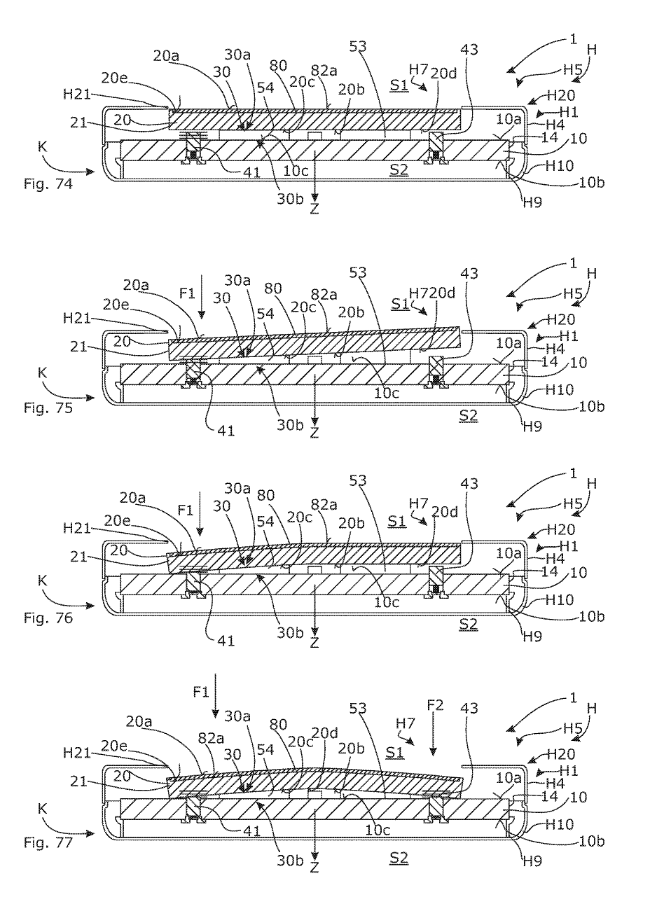

FIG. 73 the embodiment of the electrical switch device according to FIG. 42 in the representation of FIG. 63, wherein the switch device is in the output state shown in FIG. 44,

FIG. 74 as a first step of a sequence of five steps and in an embodiment with a flexible actuation part, the sectional view of the embodiment of the electrical switch device according to FIG. 68 along the line L68-L68 drawn in FIG. 67, wherein the switch device is shown in a starting position and wherein the embodiment of the switch device shown has a rigid actuation part,

FIG. 75 the embodiment of the electrical switch device according to FIG. 68 in the representation of FIG. 68, wherein the switch device is shown in an actuation position, in which an external compressive force is exerted on a first lateral edge section of the actuation part from an actuation side,

FIG. 76 the embodiment of the electrical switch device according to FIG. 68 in the representation of FIG. 68, wherein a greater external compressive force is exerted in comparison to that of FIG. 75,

FIG. 77 the embodiment of the electrical switch device according to FIG. 68 in the representation of FIG. 68, wherein compared to FIG. 76 a further external compressive force is exerted on a second lateral edge section of the actuation part, which is situated opposite to the first lateral edge section,

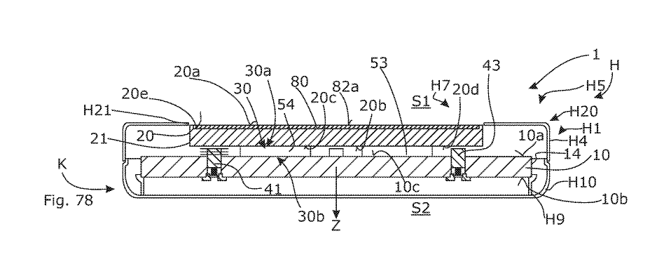

FIG. 78 the embodiment of the electrical switch device according to FIG. 64 in the representation of FIG. 68, wherein in a further operating state compared to FIG. 77 no external pressure force is exerted on a lateral edge section of the actuation part,

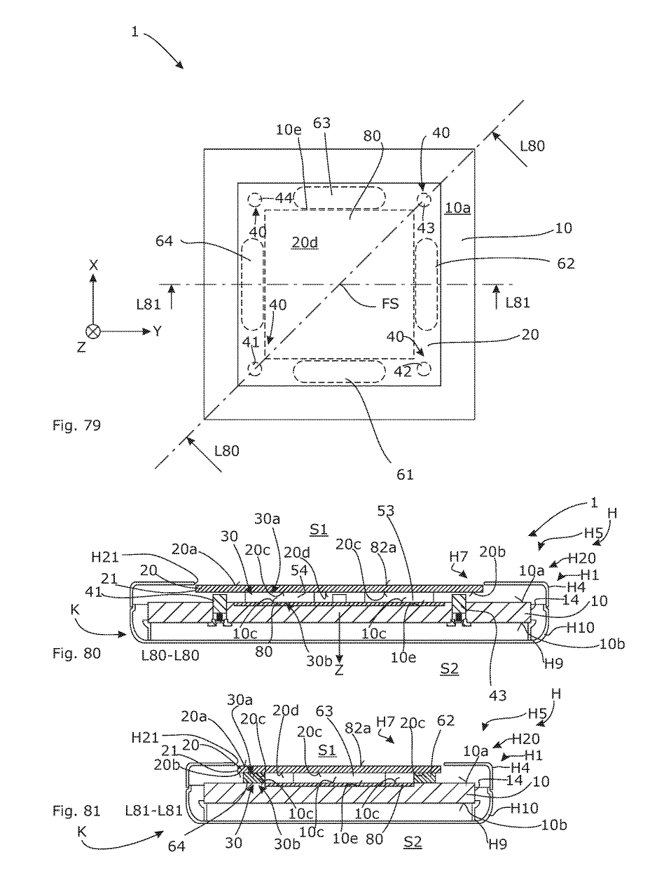

FIG. 79 a plan view of a further embodiment of the electrical switch device, wherein the sensors are shown dashed as hidden parts in the plan view, wherein the connection device is designed differently than in the previous Figures and wherein a display is integrated in the main body,

FIG. 80 a sectional view of the embodiment of the electrical switch device according to FIG. 79 along the line L80-L80 drawn in FIG. 79,

FIG. 81 a sectional view of the embodiment of the electrical switch device according to FIG. 79 along the line L81-L81 drawn in FIG. 79,

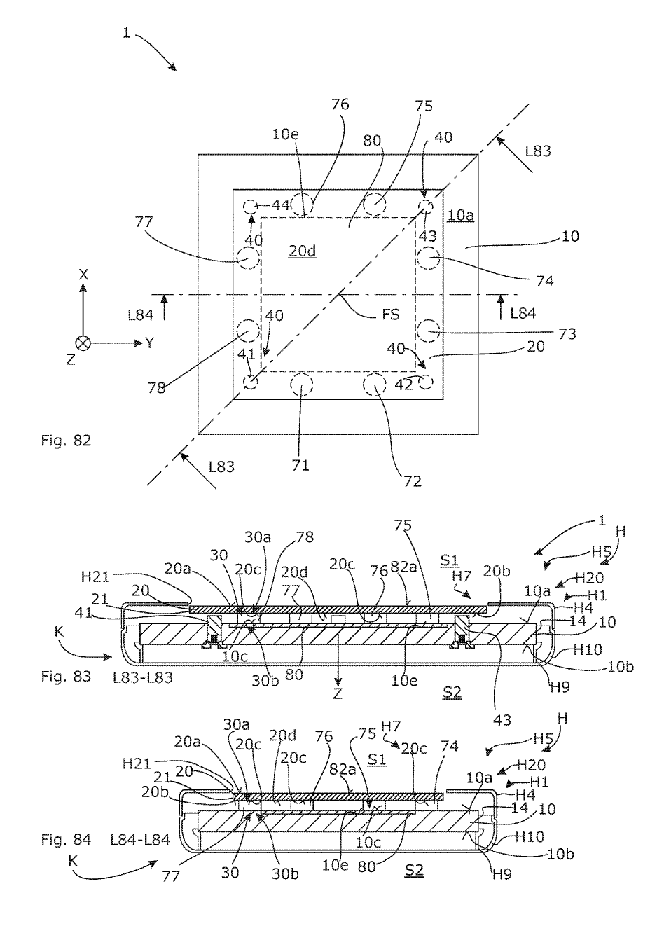

FIG. 82 a plan view of a further embodiment of the electrical switch device, wherein the sensors are shown dashed as hidden parts in the plan view, wherein the connection device is designed differently than in the previous Figures and wherein a display is integrated in the main body,

FIG. 83 a sectional view of the embodiment of the electrical switch device according to FIG. 82 along the line L83-L83 drawn in FIG. 82,

FIG. 84 a sectional view of the embodiment of the electrical switch device according to FIG. 82 along the line L84-L84 drawn in FIG. 82,

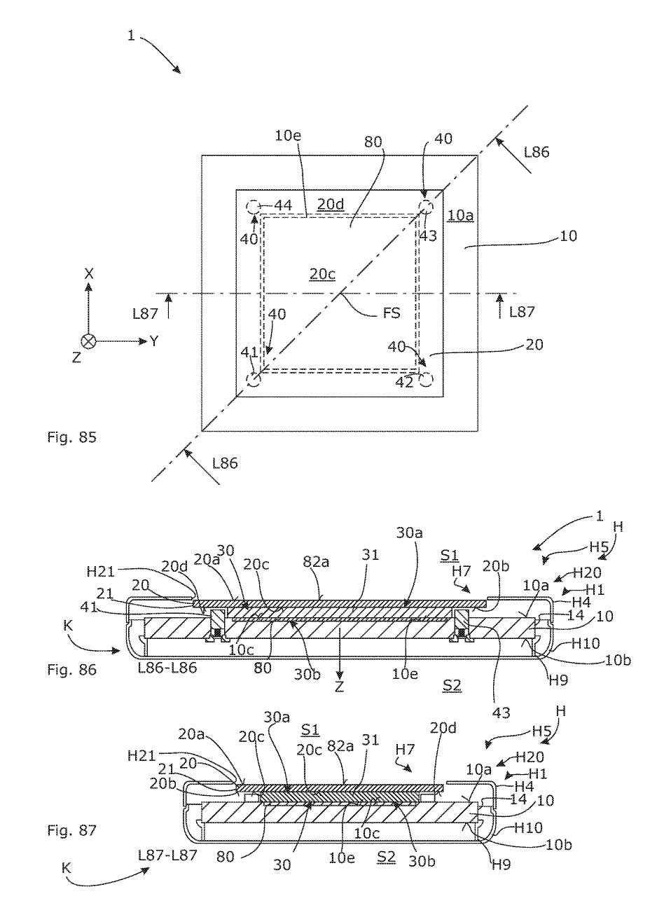

FIG. 85 a plan view of a further embodiment of the electrical switch device, wherein the sensors are shown dashed as hidden parts in the plan view, wherein the connection device is designed differently than in the previous Figures as a transparent layer, and wherein a display is integrated in the main body,

FIG. 86 a sectional view of the embodiment of the electrical switch device according to FIG. 85 along the line L86-L86 drawn in FIG. 85,

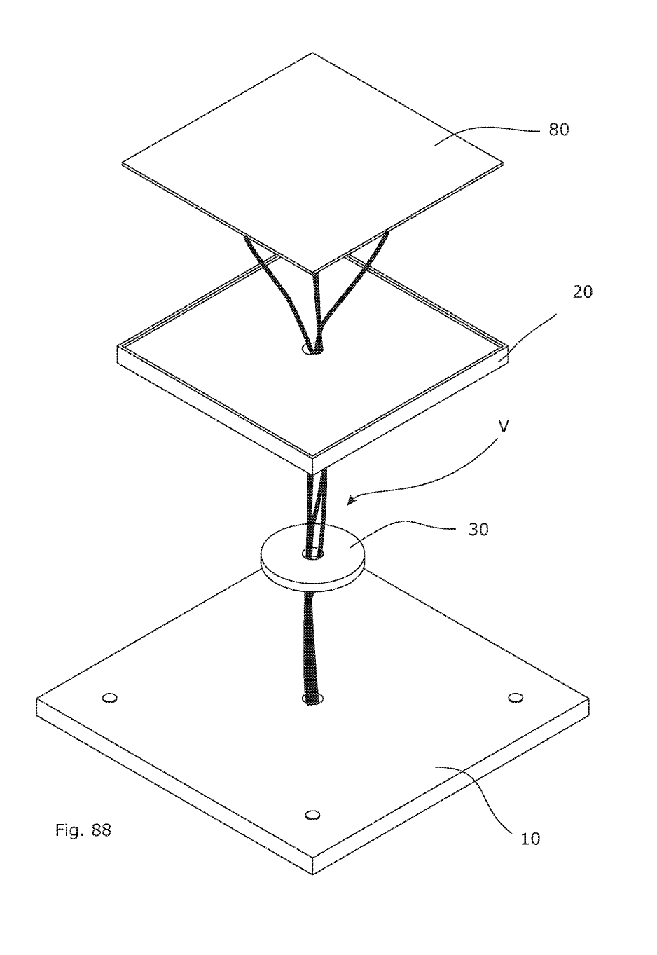

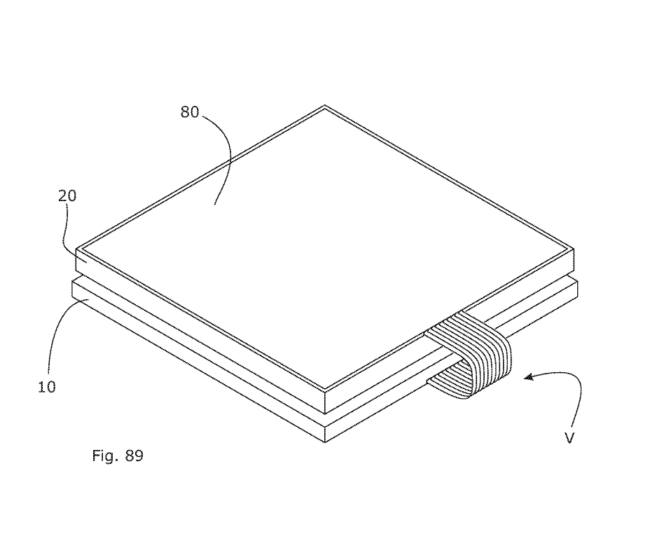

FIG. 87 a sectional view of the embodiment of the electrical switch device according to FIG. 85 along the line L87-L87 drawn in FIG. 85,

FIG. 88 a perspective exploded view of an embodiment of the electrical switch device with a representation of the electrical connection of a display integrated in the actuation part to electrical components of the main body,

FIG. 89 a perspective view of a further embodiment of the electrical switch device compared to that shown in FIG. 88, with a representation of the electrical connection of a display integrated in the actuation part,

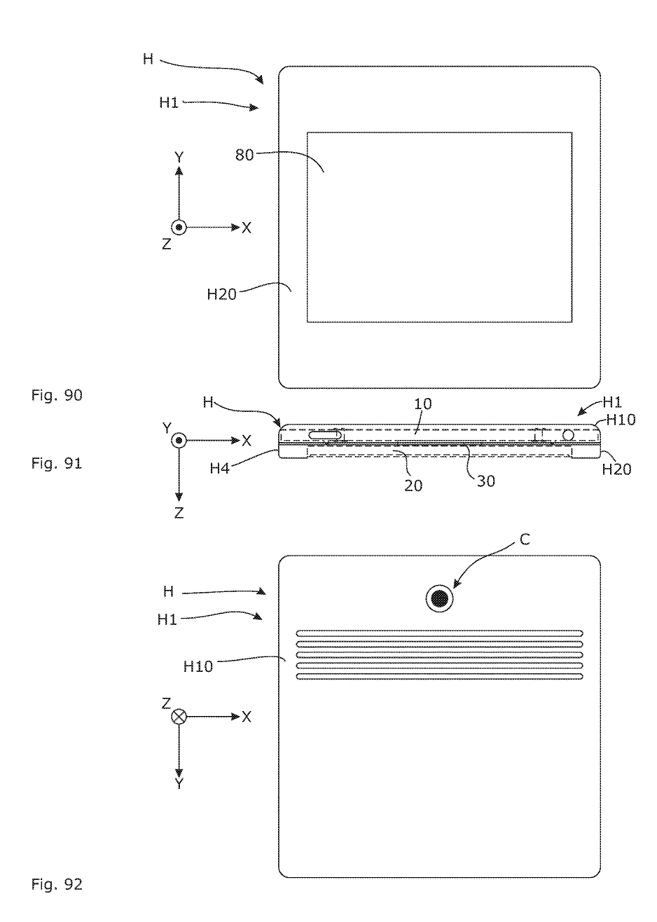

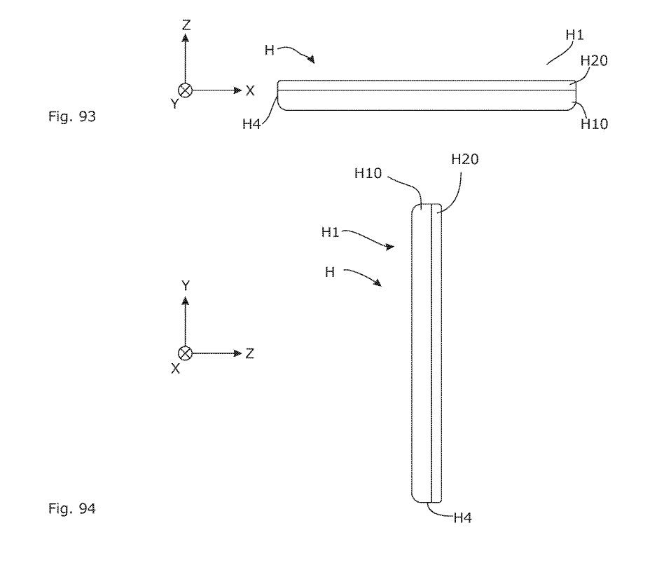

FIGS. 90 to 94 representations of a further embodiment of the electrical switch device with a housing,

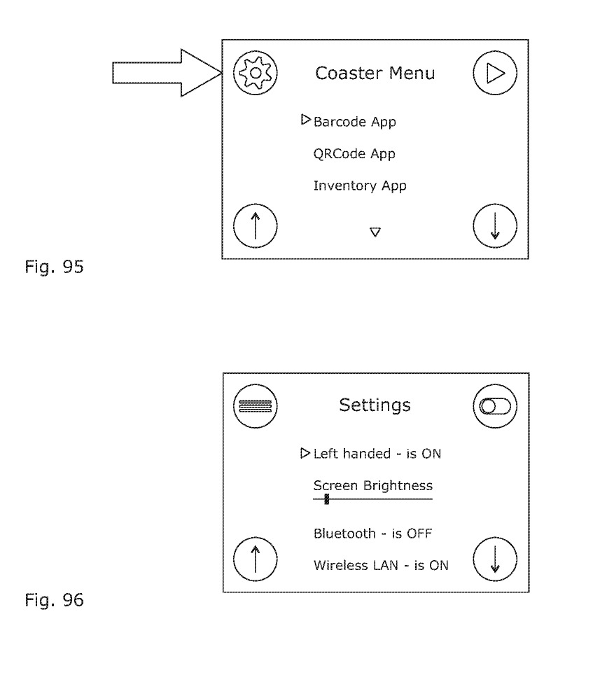

FIGS. 95 through 102 display formats of a display used in embodiments of the switch device,

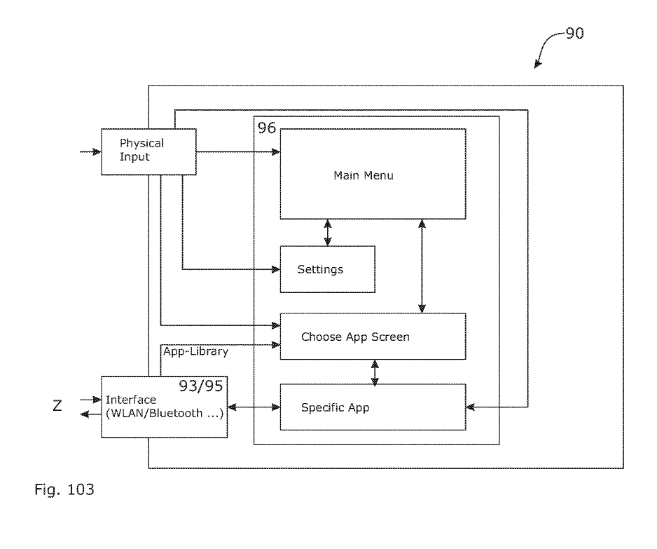

FIG. 103 a flow diagram for a logistics system that can be implemented with embodiments of the switch device with a display,

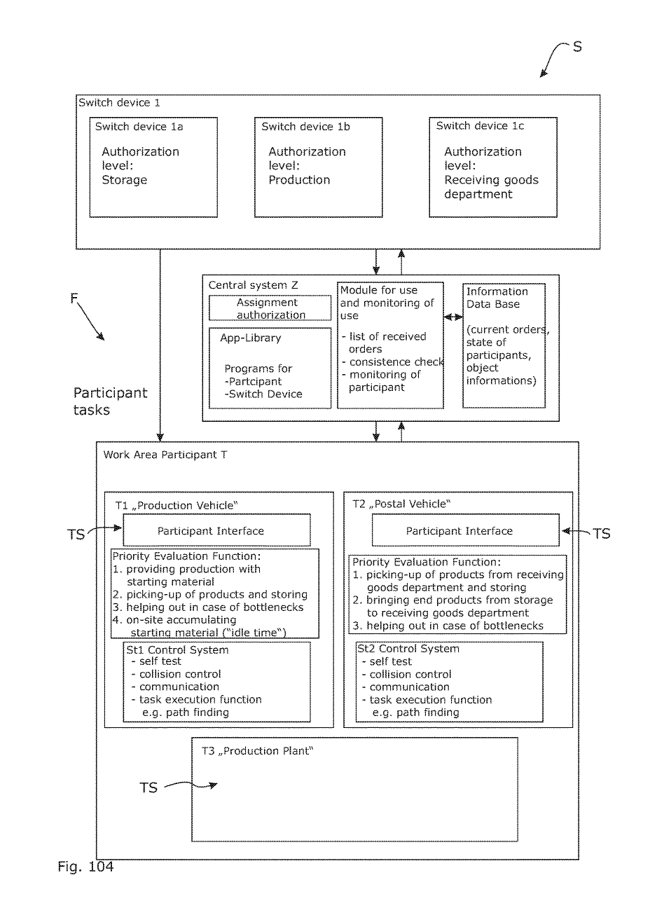

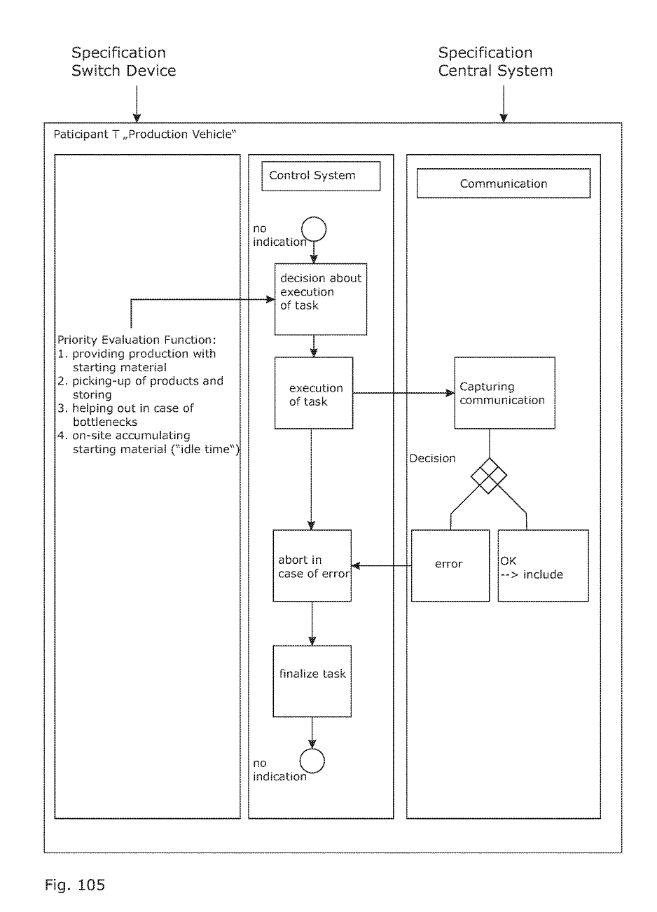

FIG. 104 a representation of the menu control, with which menu displays with tasks to be carried out are displayed in visual form in a display of an embodiment of a switch device,

FIG. 105 a functional representation of one embodiment of an operating system,

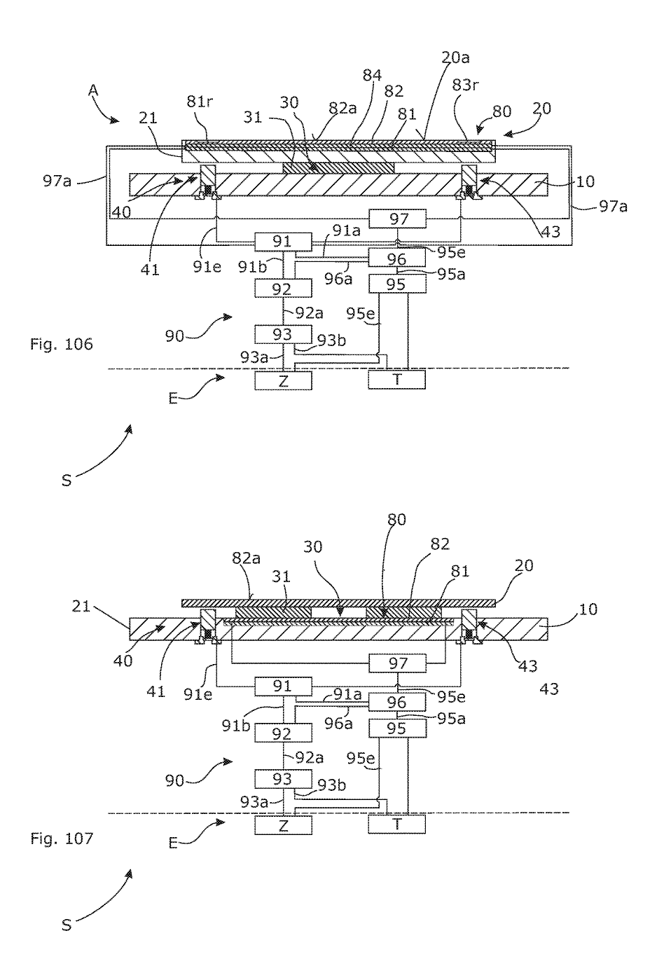

FIG. 106 a functional representation of one embodiment of the switch device with a display and a processing device, and with an external operating device with a central system and external participants, wherein the display is arranged in the actuation part,

FIG. 107 a functional representation of one embodiment of the switch device with a display and a processing device, and with an external operating device with a central system and external participants, wherein the display is arranged in the main body.

According to the invention an electrical switch device 1 for generating a plurality of switch states is provided, which can be accessed by a control device via electrical conductors or an electrical contact, in particular for generating adjustment commands for an actuating device. To generate the switch states the electrical switch device 1 is actuated on an actuation side S1 of the same. In the representations in the Figures, a Cartesian coordinate system with an x-axis, a y-axis, or thickness direction Z and a z-axis is shown. The z-axis extends in the thickness direction Z of the electrical switch device 1. In relation to the thickness direction Z of the electrical switch device 1, a rear side S2 of the electrical switch device 1 of the same is located in the Z direction opposite to the actuation side S1.

With the switch device 1, a participant task to be carried out by one or more participants T or T1, T2, T3 of the operating system S can be determined, and if necessary displayed, and submitted as a task execution command over a transmission path 93a to the central system Z or to one or more participants T or T1, T2, T3 of the operating system S, which can be an industrial operating system S and in particular a warehouse system or a production plant.

The electrical switch device 1 has a main body 10 with a first or upper surface or connection surface 10a, which is facing the actuation side S1 of the electrical switch device 1, and a second or lower surface 10b which is located opposite the upper surface 10a. The main body 10 may in particular be plate-shaped, and as such, rectangular in particular. The surface extension of the main body 10 extends transverse to the thickness direction Z and along the X coordinate and the Y coordinate. The X coordinate can be defined in particular as a central connecting line for the area centroids of each of the smallest cross sectional areas that result along a longitudinal direction, or an averaged connection line through these.

Furthermore, the electrical switch device 1 has an actuation part or an actuation plate 20, which extends transverse to the thickness direction Z and which, viewed in the thickness direction Z, is arranged on the main body 10 on the side of its first surface 10a. The actuation part 20 can be designed in particular as an actuation plate. In this case the actuation part 20, as is shown in the embodiment of FIG. 1, is rectangular or at least substantially rectangular in shape, seen in plan view or in the Z direction. The term “substantially rectangular” is understood as meaning a shape in which the perimeter lines run parallel or approximately in parallel to one another, and at least one of the corner areas can have rounded corner line sections. An “approximately parallel” extension of perimeter lines relative to each other is intended to mean herein that the respective perimeter lines extend relative to each other in such a way that a maximum angle of 20 degrees exists between the tangents to the respective perimeter lines at opposite points of the respective perimeter lines. The actuation part 20 can also be oval or circular in shape, viewed in plan view or in the Z direction.

Furthermore, the switch device according to the invention has a device housing H which is formed from the plate-shaped body 10 with the connection surface 10a, which is facing an actuation side S1 of the electrical switch device 1, and a housing part H1.

The actuation part 20 has an actuation surface 20a which is facing the actuation side S1 of the electrical switch device 1, and a connection surface 20b, located opposite to this and facing the connection surface 10a of the main body 10. The actuation surface 20a appears in the plan view of the actuation part 20, in particular in the thickness direction or the Z direction.

The main body 10 can be designed in particular as a circuit board arrangement, which has a circuit board 10L made of a circuit board material, and electronic components integrated with this. In the representation of FIG. 2 a plurality of electronic components K are arranged on the lower surface 10b of the main body 10, that are connected to conductor tracks of the circuit board 10L. The electronic components K can also be implemented in ways other than that shown.

Furthermore, the electrical switch device 1 comprises a connection device 30 with at least one connection layer made of an elastic material. It can also be provided that the connection device 30 consists of at least one connection layer, i.e. that the switch device 1 does not comprise any further connection means. Each of the at least one connection layers can be designed to be contiguous in its surface extension. In other embodiments of the switch device 1 it can be provided that the at least one connection layer or a single one of the at least one connection layers has or have a recess, extending in its thickness direction Z and passing through the entire thickness of the connection layer. The at least one connection layer of the connection device 30 or the connection device 30 is generally attached with a first surface 30a to a connection area or inner area 20c, viewed in the Z-direction, of the connection surface 20b of the actuation part 20, and with a second surface 30b is attached to an inner area 10c of the connection surface 10a of the main body 10, or is connected to the respective inner area 10c, 20c.

In the embodiment of FIG. 1 the connection device 30 consists of a connection layer 31, which is attached with a first surface 31a to a connection area or inner area 20c, viewed in the thickness direction, of the connection surface 20b of the actuation part 20, and is attached with a second surface 31b to an inner area 10c, viewed in the thickness direction, of the connection surface 10a of the main body 10, or is connected to the respective inner area 10c, 20c.

The elastic material can be—in particular in any of the embodiments mentioned herein—a self-adhesive material, so that the connection layer 31 adheres to the inner areas 10c, 20c. Alternatively or additionally thereto, as is shown in an example in FIG. 16, it can be provided that the connection layer 31 is affixed by means of an adhesive layer to one of the inner areas 10c, 20c or to both of the inner areas 10c, 20c. In particular, in this arrangement it can be provided that the connection device 30 is formed from a connection layer 31, a first adhesive layer 30i, situated between the connection layer 31 and the connection surface 10a of the main body 10, and of a first adhesive layer 30i, situated between the connection layer 31 and the connection surface 10a of the main body 10, or is composed of these layers. The adhesive material can in particular be an elastic material.

In the embodiment of the switch device with a central connection layer 31, as is shown in FIGS. 1 to 3, the connection layer 31 can extend over the entire connection surface 10b or the entire connection surface 20b, in case one of the connection surfaces is larger than the other in at least one extension direction, and depending on which of the connection surfaces is greater. Alternatively, the size of the inner areas 10c, 20c, as is shown in FIGS. 1 to 3, can also be defined in such a way that in terms of surface area it is no larger than 75% of the size of the connection surface 20b of the actuation part 20, or is located within a circle whose area is no larger than 75% of the size of the connection surface 20b of the actuation part 20. Alternatively or additionally, it can be defined so that the area centroid FS of the actuation surface 20a of the actuation part 20, viewed in its surface extension, is situated within the inner area 20c of the connection surface 20b of the actuation part 20 and within the connection layer 31.

In the embodiment of the switch device in accordance with FIGS. 1 to 3, the actuation part 20, viewed from the area centroid FS, projects beyond the connection layer 31, so that the switch device 1 comprises an area 20d protruding beyond the connection area or inner area 20c of the connection surface 20b, viewed in the surface extension of the main body 10. It can be provided in particular that the above area 20d completely surrounds the connection area or inner area 20c or the connection layer 31, i.e. it encloses the connection area or internal area 20c or the connection layer 31. The protruding area is labelled with the reference numeral 20d. In the embodiment of FIG. 1 this is designed so that it encircles the connection layer 31. The connection surface 20b of the actuation part 20 is then formed from the connection area 20c and the protruding area 20d.

The material of the connection layer 31 is elastic, to the extent that it generates a return force when compressed. The material of the connection layer 31 can in particular be formed of an acrylic material. In particular, the material can be a foam-like acrylic material. In particular, a material which is both double-sided self-adhesive and elastic from the field of industrial adhesive technology can be used, as is sold for example under the product name “ACXplus” by the company “tesa SE”. The connection layer 31 can also be formed from silicone or a foam material. The connection layer 31 can also consist of a foam material with acrylic components. In particular in the event that a display is arranged in the main body 10 and the display viewed in the thickness direction Z is located at least partly within the connection layer 31, the connection layer 31 can be formed from an optically transparent material, so that display elements positioned behind the connection layer 31 are visible.

The thickness of the connection layer 31 in the Z direction can be between 0.2 mm and 10 mm, but preferably between 0.2 mm and 5 mm.

The housing part H1 of the housing device H comprises: a side wall H4, which at least in some sections surrounds the connection device 30, provided this is part of the switch device 1, and the actuation part 20 viewed in the thickness direction Z, and an edge section H5 which adjoins to the side wall H4 towards the actuation side S1 and forms a central opening H7, in which the display 80 extends at least in some sections.

The side wall H4 extends along the Z direction and can be designed as a wall continuously surrounding the actuation part 20. Also, the side wall H4 can be designed in such a way that this surrounds the actuation part 20 in some sections along its circumference, that is, it has e.g. a plurality of recesses arranged distributed along the circumference of the actuation part 20. The side wall H4 can begin e.g. at the side of the actuating part 20 and in particular, adjoin to the resulting outer surface 14 viewed in the Z direction.

Also, as shown in FIGS. 2 and 3, the housing part H1 can comprise a holding device H9, which receives the main body 10 and to which the main body 10 can be attached. The holding device H9 can be designed as a base, or in accordance with FIG. 2, as a support arm.

The housing part H1 according to one embodiment comprises a base section H10 and a cover section H20. The holding device H10 can be designed as an attachment to the base section H10. The base section H10 and the cover section G20 can be manufactured together as one piece, e.g. by a casting process and in particular, a plastic injection moulding process. In the representation of FIGS. 1 to 3 the housing is designed as a two-part housing, wherein the base section H10 and the cover part H20 are designed as a first part and a second part respectively and the cover part H20 is mounted on the base part H10 and fixed thereto, so that the housing forms a single part overall. The base part H10 and the cover part G20 in particular can each be shell-shaped. The housing part H1 can also be designed in such a way that only the base part H10 or only the cover part G20 in particular can each be shell-shaped.

In the embodiment of FIGS. 1 to 3, the side wall H4 is located at least partially outside of the actuation part 20, viewed in the thickness direction Z. In this case the side wall H4 can surround the main body 10 along its perimeter. Adjoining the side wall H4 in the direction of the actuation side S1 is an edge section H5 of the housing part H1, which has an internal central opening H7, viewed in the Z direction. The outer edge of the actuation plate 20 extends along the inner edge H8 forming the opening H7.

In one embodiment of the switch device 1 it can be designed in such a way that the outer edge section 21 of the actuation plate 20, viewed in the Z direction, is located within the inner rim edge section H5 of the housing part H1, so that the actuation part 20 viewed in the Z direction is located within the opening H7 (FIG. 2).

In general, but in particular in this embodiment, a seal G40 can be located between the edge section H5 of the housing part H1 and an edge section of the actuation part 20, which connects these edge sections together (FIG. 16), in particular to seal the interior of the housing part H1 from the outside. In this case the seal G40 can be part of the connection device 30. This seal G40 can be formed from an elastic material, so that this supports the resilience of the connection layer 31. A section of the seal can also be located along the perimeter of the edge section H5.

A distance can also exist between the outer edge section 21 of the actuation plate 20 and the inner rim edge section H5 of the housing part H1, viewed in the Z-direction (FIG. 34), wherein a sealing device or a covering device G50, e.g. in the form of a cover ring or a cover membrane, can connect the outer edge section 21 of the actuation plate 20 and the edge section H5 of the housing part H1, to seal the interior of the housing part H1 from the outside.

In a further embodiment, if the switch device 1 comprises the seal G40, the switch device 1 can be designed without connection layer 31, so that the seal G40 forms the connection device 30.

A further embodiment of the switch device 1 can be designed in such a way that the outer edge section 21 of the actuation plate 20 viewed in the Z direction protrudes beyond the inner rim edge section H5 of the housing part H1, so that the actuation part 20 and the outer edge section 21 of the actuation plate 20, viewed in the Z direction, overlap (FIG. 16). In accordance with FIGS. 54 to 57, in a further embodiment of the electrical switch device 1 it can also be provided that the circumferential edge section H5 of the housing part H1 is connected to the actuation part 20, and in particular to an outer edge of the same. In this case it can be provided that the switch device 1 does not have a connection layer and the edge section H5 of the housing part H1 is designed as the reset device for the actuation part 20, by this being elastically deformable.

The connection layer 31 can, but does not have to, consist of an elastic material, therefore one which is able to reset the actuation part 20, if the connection device 30 has a further component that can reset the actuation part 20, e.g. a seal H40 or a connection of an edge section H5 of the housing part actuation part 20.

The electrical switch device 1 also comprises at least one sensor or at least two sensors, which is or are located between the main body 10 and the actuation part 20 and, viewed in the thickness direction Z, to the side of the connection layer 31, wherein the actuation part 20 extends transverse to the thickness direction Z and viewed in the extension of the X-Y plane, extends beyond the connection layer 31 and beyond each respective sensor.

In the embodiment of the connection device 30 with the connection layer 31 in accordance with FIG. 1, each of the at least one sensors, viewed in the thickness direction Z, is located behind the connection device 31 from the viewpoint of the area centroid of the actuation part 20.

On the basis of the respective position of the at least one sensor or sensors, a position of one region, arranged on said sensor, of the second surface in the thickness direction Z can be detected or determined. In particular, on the basis of the position of the sensors, the distance between the connection surface 10a of the main body 10 and the connection surface 20b of the actuation part 20, viewed in the thickness direction Z, at the position of the respective sensor viewed in the X-Y plane can be detected or determined.

The switch device 1 can comprise a sensor device 40, which comprises the at least one sensor and also a position determining device with a position determining function, wherein the position determining function is functionally connected to the respective sensor. The position determining function can be integrated in one of the electronic components K of the main body 10.

The embodiment of the electrical switch device 1 that is shown in FIG. 1 has four sensors 41, 42, 43, 44. These are arranged evenly distributed along the outer circumference of the edge line. In each case two sensors, namely the sensors 41 and 43 and the sensors 42 and 44, are arranged opposite one another in relation to the area centroid F of the actuation surface 20a. Each sensor 41, 42, 43, 44 can be used to detect a position of one region, arranged on said sensor, of the second surface in the thickness direction Z.

The at least one sensor or the sensors can each be designed as a sensor for detecting, in a contactless manner, the distance from the respective sensor to the point of the connection surface 20b of the actuation part 20 opposite thereto. FIG. 3 shows a sectional view of the embodiment of the electrical switch device according to FIG. 1 along the line L3-L3 drawn in FIG. 1, wherein contactless sensors in the form of optical sensors are used. FIG. 4 shows a sectional view of the embodiment of the electrical switch device according to FIG. 1 along the line L3-L3 drawn in FIG. 1, wherein contactless sensors in the form of inductive sensors are used. In the switch device 1 shown in FIG. 2 therefore, each of the sensors 41, 42, 43, 44 is designed as an optical sensor.

According to one embodiment, sensors 41, 42, 43, 44 are provided, each of which detects in a contactless manner the distance from the same to the point of the connection surface 20b of the actuation part 20 that is opposite to the respective sensor.

The sensors can not only be contactless sensors, such as optical sensors, but also magnetically sensitive sensors or ones which exploit the piezo-electric effect.

According to a further embodiment in FIGS. 15 and 16 an embodiment of the sensors 41, 42, 43, 44 is shown, in which the sensors 41, 42, 43, 44 are each mechanical sensors, which are designed e.g. as switch sensors with a switch component.

According to one embodiment of the electrical switch device 1, this can comprise a display 80 or a display panel, so that this embodiment is formed by an input and output device. The display 80 can be arranged, and in particular located, on the connection surface 10a of the main body 10 or on the actuation surface 20a of the actuation part 20. In embodiments of the switch device 1 the display 80 can be located at least partially in a recess, which is formed by the connection surface 10a of the main body 10 or on the actuation surface 20a of the actuation part 20.

In general, the switch device 1 can comprise a camera device C. In FIG. 92, a camera device C is shown schematically by a lens integrated in the housing part H1. The camera device C can comprise in particular an optical system with a lens and camera actuation device, and an image capture device. The image capture device can comprise in particular a bar code detection function, with which a bar code detected by means of the camera can be interpreted with respect to the functions contained therein.

The housing part G1, and in particular the base part H10, can also be formed from a magnetic material, to be able to arrange the housing part G1 in an application space on a metallic attachment of this application space.

In particular in the embodiments of the switch device 1 shown in FIGS. 1 to 3 and FIG. 90, the actuation part 20 comprises a display 80 or display panel, which is located in an internal display area 20e of the actuation surface 20a of the actuation part 20, viewed in the thickness direction Z. By means of the display device, a display area is provided, and possibly also an operating area for a user. The display area 20e can be designed, as shown in FIGS. 1 to 3 and FIG. 100, as a recess formed on the actuation surface 20a. The display 80, viewed in the thickness direction Z, can be located entirely or partially, i.e. at least partially, in the recess.

From a functional perspective the display 80 or the display panel is an output device. The display 80 can in particular comprise a flat image generation module 81 and a screen cover plate or support plate 82 placed over this, in the direction of the actuation side S1. The image generation module 81 can in particular be an image output device with a display device, such as a fluid display device.

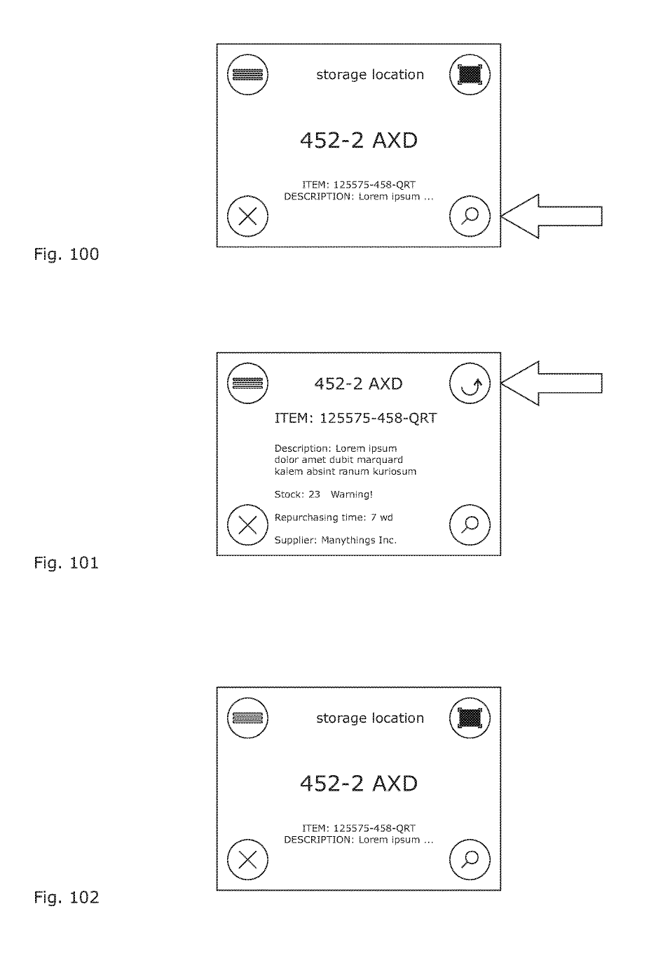

The display 80 can in functional terms also be an output device, that can additionally be designed as an input device, and in this case therefore as an input and output device. In the embodiment of the display 80 as an input and output device, this can also have a proximity-sensitive and/or touch-sensitive panel or a touch panel. The proximity and/or touch-sensitive panel 84 or touch panel can be located in particular on or under the support plate 81. In FIG. 100 an embodiment of the display 80 according to FIG. 100 is shown, in which the display 80 comprises a proximity and/or touch-sensitive panel 84.

In a further embodiment of the switch device 1 this can be designed with the proximity and/or touch-sensitive panel 84, but without the elastic connection layer 31 and the sensors for determining a value corresponding to a distance between the main body 10 and the actuation part 20.

In relation to the operational and in particular actuation functions of the switch device 1, actuation areas can be assigned on the actuation surface 20a of the same, depending on the point at which the respective sensor of the at least one sensor is located in the surface extension of the switch device 1 or viewed along the X-Y plane.

In FIG. 4, for the four sensors to 41, 42, 43, 44 and each of their specific positions on the actuation surface 20a of the switch device 1 according to FIG. 1, four actuation areas B41 or B42 or B43 or B44 are assigned. These are located in corresponding edge regions of the actuation part 20, in which the respective one of the at least one sensors is arranged. The actuation areas are located in such a way that an actuation or exertion of a compressive force F1, F2, with a minimum value in a respective actuation area leads to a reduction in the gap between the main body 10 and the actuation part 20 only in this particular actuation area, and therefore only at the sensor which is located at the respective actuation area. If a limit value G1 is exceeded, as determined by an actuation area identification function 91, due to an appropriate compressive force, then this movement is evaluated as an actuation of the switch device 1.

FIGS. 5 to 8 illustrate an actuation of an actuation area B41 in a series of steps.

The steps according to FIGS. 17 to 20 show that with at least two limit values G1, G2 on the same sensor and actuating range B41, two actuation possibilities, and thus selection options, can be implemented.

With the embodiment according to FIG. 33 it is shown alternatively or in addition, that on an actuation area, e.g. the actuation area B41, multiple actuation options and thus selection options can be implemented if on at least one actuation area two sensors are arranged, with which it can be determined using the actuation area identification function 91 whether at least one limit value G1, G3 has been exceeded on the same actuation area. Thus, at each sensor 41, 42, 43, 44, one additional internal sensor 51, 52, 53, 54, in relation to the area centroid of the actuation part 20, is arranged, each of which is located between an external sensor 41, 42, 43, 44, and the area centroid of the actuation part 20. In this context, as shown in FIGS. 35 to 38, it is provided in particular that the limit value G1 of the external sensor, seen from the viewpoint of the area centroid of the actuation part 20, is smaller than the limit value G3 of the respectively assigned internal sensor 51, 52, 53, 54, wherein in particular a factor of at least 1,1 can be provided.

In FIGS. 44 to 47 it is shown that the actuation part can be designed to be elastic in its surface extension, in such a way that for at least two actuation areas located opposite to each other, e.g. actuation areas located diametrically opposite to each other (e.g. B41 and B42) or actuation areas located on the same side edge of the actuation part 20 (e.g. B41 and B43), or optionally also three or four actuation areas (e.g. B41, B42, B43 and B44) a sufficient reduction in distance from two sensors can be obtained by appropriate actuation (F1, F2) while providing an appropriate resilience of the actuation part 20.

In order to implement the actuation function of the switch device 1 when a plurality of sensors of a switch device 1 are present, the areal relation of the actuation areas viewed in the thickness direction Z at points is equal to the spatial relation of the points at which the S are located. In addition, the regions are viewed in the thickness direction Z and the positions of the sensors are located on top of one another, so that the respective relation is obtained.

The term “areal relation” is understood herein to mean the relative assignment of the actuation areas in the X-Y plane. The term “positions of the sensors” is understood to mean the positions of the sensors in the X-Y plane.

In FIGS. 58 to 66 different embodiments of a connection device 30 are shown, which is viewed in the thickness direction Z and is centrally arranged within the upper surface or connection surface 10a of the main body 10.

FIGS. 67, 79, 82 show embodiments of the switch device 1, in which the connection layers are in an external area of the connection surface 20b of the actuation part 20 and are attached with a second surface 30b to an external region of the connection surface 10a of the main body 10.

In the embodiment of the switch device 1 according to FIG. 79, the connection device 30 thereof does not have a central connection layer. Rather, the connection device 30 is formed of a plurality of connection layers 61, 62, 63, 64, that are arranged around the area centroid of the actuation part 20, distributed along the outer edge section 21 of the actuation part 20. This arrangement of distributed connection layers 61, 62, 63, 64 can also be used in other embodiments described herein. The connection layers 61, 62, 63, 64 are oblong shaped.

In the embodiment of the switch device 1 according to FIG. 79 the display 80 is integrated in the base plate 10, wherein the display 80 can be located on the first surface 10a of the base plate 10. In this case the actuation part is formed of a transparent material, so that views of the display 80 can be identified on the actuation side 51.

In the embodiment of the switch device 1 according to FIG. 82 it has a connection device 30, which also has no central connection layer, but compared to the switch device 1 according to FIG. 79 comprises circular connection layers 61, 62, 63, 64, that are arranged around the area centroid of the actuation part 20, distributed along the outer edge section 21 of the actuation part 20. In the embodiment of the switch device 1 according to FIG. 82 also, the display 80 is integrated in the base plate 10.

The switch device 1 according to FIG. 79 or 82 can comprise an additional central connection layer 31 located at the area centroid of the actuation part 20, e.g according to FIG. 1.

In FIGS. 88 and 89, examples are shown of different embodiments of an electrical connection of the display 80 to electrical components K of the base plate 10 using a connection device V. In the embodiment shown in FIG. 88 the switch device 1 comprises a wiring harness of cables, which are connected both to electrical components of the display 80 and to electrical components K of the base plate 10. This cable harness extends through a central opening in the actuation part 20 and, in the case of a centrally arranged connection layer 31, a central opening of the connection layer 31. In the embodiment of the switch device 1 shown in FIG. 89, such a wiring harness is guided along a side of the switch device 1, i.e. outside of the actuation part 20 and the connection device 30 to the side, and on the same side along the side of the base plate, from where a wiring of the cables to electrical components K of the base plate 10 is implemented.

In general, and in particular when a plurality of sensors of a switch device 1 are present, the actuation areas are located in such a way that by actuating or exerting a compressive force with a minimum value in a respective actuation area
depending on the design of the connection device and in particular the shape, number and position or arrangement of the at least one connection layer
in the direction of the actuation side S1 towards the main body 10
   a sufficient reduction occurs in the distance between the main body 10 and the actuation part 20 only in this particular actuation area, and therefore only on the sensor 40 which is located at the respective actuation area or control field. The sensor 40 and a function processing device or evaluation device 90 functionally related thereto (FIGS. 106 and 107) is designed in such a way that in the event of such an action, the actuation of the respective actuation area is detected by means of an actuation area identification function 91.

If a proximity-sensitive and/or touch-sensitive panel 82 is present, which is arranged e.g. on a plate-shaped image generation module 81, this can be visualised using an image production generator 97. A respective control field in the display area of a display panel or in the e.g. plate-shaped image generation module 81 of the display 80 is visualised by being generated by means of the image production generator 97. It may be the case that control fields are displayed at other positions, in relation to the position of the sensors 40.

The evaluation device 90 can be so designed that the activation area identification function 91 of the at least one sensor of the switch device 1 receives signals via a functional conductor 91e which correspond to a sufficient reduction of the distance between the main body 10 and the actuation part 20, at which the actuation area identification function 91 identifies an actuation. In this way the detection by means of a sensor 40 can be confirmed by the actuation area identification function 91.

If a proximity sensitive and/or touch-sensitive panel 82 is present, the respective control field which in its position may correspond to the relative position of a display actuation area, and in particular can be located therein, can be displayed on a display actuation area using a menu control module 96 and an image generator 97 functionally connected thereto, by means of the image generation module 81 functionally connected to the latter, or in the image generation module 81, thus in the display 80. The activation area identification function 91, which is functionally connected via the conductor 97a to the proximity-sensitive and/or touch-sensitive panel 82, can be used to detect whether the control panel displayed in the display 80 has been actuated by a manual gesture.

Using the menu control module 96, depending on the user functions provided and on a menu format rendered with these on the display 80, meanings can be assigned to the respective control field, which in particular are associated with tasks to be executed by an external operating device E, and in particular by participants T or a central system Z.

In general, and in particular in the case of an embodiment of the switch device 1 with the proximity-sensitive and/or touch-sensitive panel 84 and without the connection device with an in particular elastic connection layer 31, optionally also without actuation part 20, and without sensor system 40, the switch device 1 can be so designed that the actuation of a control field in a menu selection can be effected by selecting an option specified in the control area by touching or approximately touching such an option with the finger by a switch device user, which option is made available in the display area of the display 80.

In general, and in particular in the case of an embodiment of the switch device 1 without a proximity-sensitive and/or touch-sensitive panel 84 and without the elastic connection layer 31, optionally also without operating part 20 and sensors 40, the switch device 1 can be so designed that the actuation of a control field in a menu selection can be effected by conventional activation or selection of an option specified in the control area, which is made available in the display area of the display 80, thus e.g. by means of keys or a computer mouse or other manual input device.

The operation of a control field in a menu selection by touch or approximate touch and alternatively or additionally by conventional activation, can also be provided in the embodiment with the elastic connection layer 31 and sensors 40.

As shown in FIGS. 100 and 101 shown, in an embodiment of the switch device 1 with the elastic connection layer 31 and sensors 40, the sensor signals generated by the at least one sensor, which correspond to distance values of distances between the main body 10 and the actuation part 20 as a function of an actuation force F1, F2 exerted on the respective actuation area, are passed via functional conductors 91e, each connected to one sensor, to the actuation area identification function 91. From these sensor signals, on the basis of pre-defined minimum actuation values this function determines whether, based on the respective actuation force F1, F2, an actuation area has been actuated, in the embodiment of FIG. 1 this being one of the actuation areas B41 or B42 or B43 or B44. The actuation area identification function 91 determines, on the basis of at least one pre-defined minimum actuation value assigned to each sensor, whether the distance between the main body 10 and the actuation part 20 at the site of the sensor, which is located on an actuation area being moved by an actuation force F1, F2, exceeds a pre-defined minimum actuation value. If this comparison finds such an excess value, the actuation area identification function 91 determines that an actuation of the actuation part 20 has taken place at the respective actuation area. It can also be provided here that a plurality of limit values G1,G2 or G1, G3 are compared with the sensor values of a sensor or the sensors, so that a plurality of force levels of an actuation force F1, F2 can be determined as different actuations on the same actuation area. The at least one actuation minimum value can be stored in the actuation area identification function 91 as at least one pre-defined value. Alternatively or in addition, the at least one actuation minimum value can be supplied to the actuation area identification function 91 via an interface 95 and by means of the menu control module 96, for example again via a menu function which can be selected via the actuation of an actuation area in a specified menu level or menu selection.

If the actuation area identification function 91 determines that an actuation of an actuation area has taken place on the basis of the procedure described above or in some other manner, such as touch or proximity, then the actuation area identification function 91 sends this actuation information over a functional line 91b to an actuation module 92.

Depending on the embodiment of the switch device 1, the actuation information sent over a functional line 91b to an actuation module 92 can also be generated differently, e.g. by touching or approximately touching, in the case of an input gesture of the finger by a switch device user, in a control area or control field generated by the generator 97 in the image generation module 81, which is made available in the display area of the display 80 as input option, or by conventional activation of such an option by means of keys or a computer mouse or other manual input device.

Information about a particular participant task to be executed, by means of which the menu control module 96 provides a logical task question in a respective control field, in particular in the form of an option, is made available to the control module 92 via a functional line 96a. An option or logical question can be, e.g.: “Send a number N1 of storage objects O1 to a goods out area”.

The menu control module 96 can also be so designed that this is used to display the selection of a menu level or a menu selection format, in particular with a selection option using a selectable selection format in or on the actuation area, in order to identify a participant task to be executed and to display it. For this purpose the menu control module 96 displays one task via one menu or one request via a menu, e.g. a request via one menu level, i.e. a menu selection format, on the display 80. The selection of a menu format in a displayed menu selection is made via an actuation detected using the actuation area identification function 91, in particular based on one of the options described herein, and by on the basis of this actuation, actuation information being transmitted over the functional line 96a to the menu control module 96, which thereupon provides the selected menu format on the display 80.

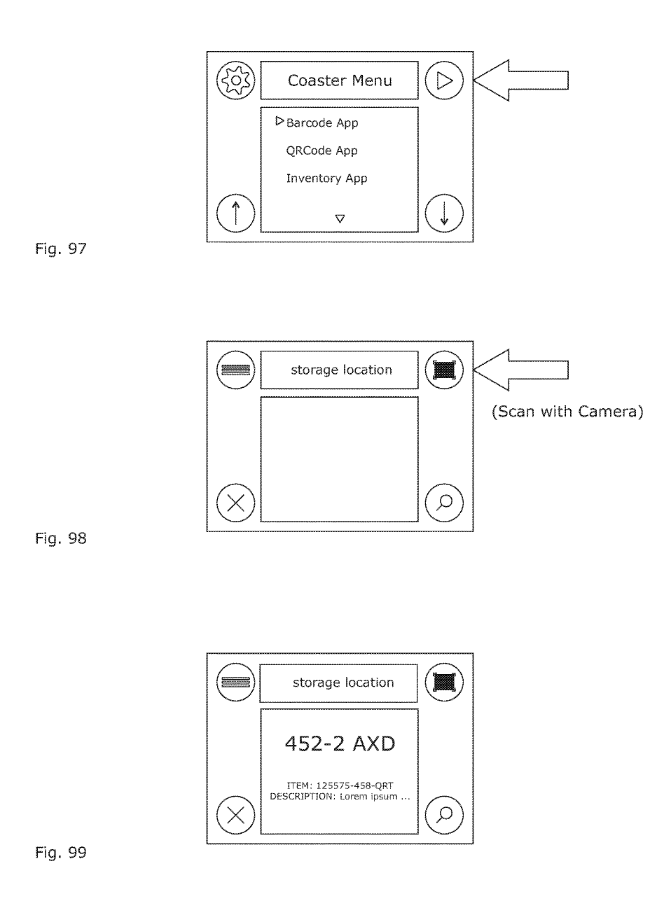

The menu control module 96 can also be designed such that in this manner, i.e. with selection options using a selectable selection format, an application function, designated in FIG. 97 with the label “app”, or one of several application functions, can be selected by an actuation as described. It can be provided here that the application function “app” can be called up and is transmitted via the interface 95 by such an actuation, or is available in the menu control module 96 and can be selected there. Thus, according to one embodiment of the operating method, in the selected application function App, at least one participant task to be completed by one or more participants T; T1, T2, T3 of the operating system S can be selected on the display 80.

From the information about the requested participant task and from the actuation information, the actuation module 92 determines a task execution command, which is transmitted over an output line 92a to an output interface 93. The task execution command is a command for a participant T, to execute a task TA. The output interface 93 transmits the signal to an external unit, such as the central system or a participant T or T1, T2, T3 of the operating system S.

Alternatively, it can be provided that the information about the requested participant task, instead of being sent over the functional line 96a, is sent over the functional line 91a to the actuation area identification function 91, which transmits the information about the requested participant task together with the actuation information over the functional line 91a to the output interface 93.

The output interface 93 transmits the task execution command over a transmission path 93a to the central system Z or to one or more participants T or T1, T2, T3 of the operating system S.

The output interface 93 can in particular comprise a transmission function for sending the task execution commands over a network link in general, and in particular by radio. Furthermore, the output interface 93 can also be configured in such a way that the task execution command is sent to the central system Z and all the participants, or to all participants and not to the central system Z. The output interface 93 can also be designed in such a way that these alternatives can be individually selected on the basis of a menu selection specified by the menu control module 96, or in a corresponding menu level.

The functions described in relation to FIGS. 104 and 105 can also be combined and integrated with each other in other ways, so that in particular the specified functional connections can be simple functional interfaces of a programming system.

Therefore, the switch device according to any one of the embodiments described herein can be used to determine a participant task to be executed by one or more participants T or T1, T2, T3 of the operating system S, and where appropriate display it, and to transmit it as a task execution command over a transmission path 93a to the central system Z or to one or more participants T or T1, T2, T3 of the operating system S.

The functions of the evaluation device 90 described herein can in particular be integrated in the components K of the main body 10, and thus generally form part of a mobile, and in particular portable, switch device and in particular of the switch device 1 according to an embodiment shown in FIGS. 1 to 88. However, the described functions of the evaluation device 90 can be integrated in a switch device integrated which is designed as a smartphone or a laptop, and in particular as a portable computer.

In FIG. 103, the functions of the switch device are shown in a user-related form. The actuation of the switch device in conjunction with a menu selection displayed in a control field by the menu control module 96, is identified with the block “Physical input”. An example of the menu selection displayed in a control field by the menu control module 96 is shown in the block designated with the reference numeral “96”.

In sections of the actuation areas, at least one spatially distinct surface section 81r, 83r or one spatially distinct surface structure can be formed on the display interface 82a, for the tactile sensing of the respective actuation area. The spatially distinct surface sections can be designed as recessed and/or raised positions relative to the surface extension of the display surface 82a. In this way, a user can sense an actuation area by touch within the otherwise flat, i.e. planar extending surface 11a. The term “physically distinct structure” is herein understood to mean that this has a plastic structure, thus a shape in which the surface points of the structure can only be defined by means of all three spatial coordinates.

FIG. 103 shows functions and steps of one embodiment of the operating method. In general, in the operating method a plurality of switch devices can be used, and optionally in particular at the same time.

According to one embodiment of the operating method, for all or individual switch devices used, authorizations can exist for the actuation of participant tasks to be executed by participants or for task areas such as storage, production, goods receipt, to each of which a participant task to be executed belongs. It can be provided as part of this that in order to actuate and issue commands for carrying out a participant task to be executed, or to select an associated task area, a corresponding authorization must be enabled. Such a security function can be provided in the central system (“Assignment authorization”). The enabling can be accessed via the interfaces 93, 95 through appropriate actuation of the switch device in conjunction with a menu selection displayed in a control field by the menu control module 96. It can also be provided that appropriate authorizations are issued by the central system Z, by the central system Z being enabled based on the receipt of an access code from a switch device.

According to one embodiment of the operating method, after selection of a participant task a selected participant task is submitted by actuation of the switch device 1 to multiple participants T; T1, T2, T3. As examples of a participant T, a production vehicle T1, a post vehicle T2 and a production plant T3 are shown.

The operating system S, in which the operating method takes place, can in particular be a storage system wherein at least two participants T; T1, T2, T3 are operating devices such as e.g. forklift trucks, cranes, moveable vehicles on a storage rack, or a combination of at least one of selection of the same.

The participants T or T1, T2, T3 can each comprise a participant system TS, which has an interface in particular for receiving a task execution command submitted by an output interface 93. The participant system TS can also have a priority evaluation function, with which task execution commands received over a working period are each subject to a prioritization of the participant tasks received over a specified working period that correspond to the task execution commands received. The meaning and content of tasks which belong to a respective task execution command can be available in the participant T or T1, T2, T3. Alternatively or additionally it can be provided that where appropriate and in particular on automatic request, these are provided by the relevant participant T or T1, T2, T3 to the central system Z by the central system Z to the respective participant T or T1, T2, T3.

In each or in more than one of the participants T or T1, T2, T3, or the one priority evaluation function, a function for consistency checking can take place by comparison of the participant tasks received at a point in time or in a time period in the active participants T or T1, T2, T3, e.g. by formation of an overall list of the participant tasks in each participant system TS and a reconciliation of the participant tasks between the participants T or T1, T2, T3, in such a way as to avoid the highest priority being assigned to the same task. Alternatively or additionally, such a consistency checking function can also be provided in the central system Z. In the event that the highest priority has been assigned to the same task, a reconciliation is carried out by shifting the priorities, e.g. according to a predetermined prioritization of the participants concerned, in such a way as to avoid the highest priority being assigned to the same task.

In this way, by means of a control system the task with highest priority is processed by each respective participant T or T1, T2, T3, in such a way that each participant T or T1, T2, T3 executes a task with highest priority. A control system for this purpose comprises in particular a task implementation function, with which the content-based participant tasks, which belong to a given received task execution command, are executed by the relevant participant T or T1, T2, T3.

It can also be provided that this operating method proceeds over a longer period of time, such as a half or full day or several days, so that several participant tasks are therefore performed. The time period involved can be at least three times the period of time required for the task which is to be executed in the shortest time.

1. Switch device (1), comprising:
a housing device (H) with a plate-shaped body (10) with a connection surface (10a), which is facing an actuation side (S1) of the electrical switch device (1), and with a housing part (H1),
a plate-shaped actuation part (20) arranged thereon, viewed in the thickness direction (Z), with an actuation surface (20a) facing the actuation side (S1) and a connection surface (20b) located opposite to this,
a display (80) integrated in the actuation part (20) for displaying images on the actuation side (S1), wherein the housing part (H1) comprises: a side wall (H4), which surrounds the connection device (30) and the actuation part (20) viewed in the thickness direction (Z) at least in some sections, and an edge section (H5) which adjoins to the side wall (H4) towards the actuation side (S1) and forms a central opening (H7), in which the display (80) extends, at least in some sections,
a connection device (30) having at least one connection layer (31) made from an elastic material, which is attached to an inner area (20c) of the connection surface (20b) of the actuation part (20) and is fixed with a second surface (30b) to an inner area (11) of the connection surface (10a) of the main body (10),
at least one sensor (41, 42, 43, 44), which is located between the main body (10) and the actuation part (20) and viewed in the thickness direction (Z), is located at the side of the connection device (30), so that each sensor (41, 42, 43, 44) can be used to detect a position of one region, arranged on said sensor, of the second surface in the thickness direction (Z).

2. (canceled)

3. Switch device (1), comprising:
a housing device (G) with a plate-shaped body (10) with a connection surface (10a), which is facing the actuation side (S1) of the electrical switch device (1), and with a housing part (G1),
a plate-shaped actuation part (20) arranged thereon, viewed in the thickness direction (Z), with an actuation surface (20a) facing the actuation side (S1) and a connection surface (20b) located opposite to this,
a display (80) integrated in the actuation part (20) for displaying images on the actuation side (S1), wherein the housing part (H1) comprises: a side wall (H4) extending away from the main body (10), which viewed in the thickness direction (Z) surrounds the actuation part (20) at least in some sections, and an edge section (H5) which adjoins to the side wall (H4) towards the actuation side (S1) and forms a central opening (H7) in which the display (80) extends, at least in some sections,
a connection device (30) having at least one connection layer (31) made from an elastic material, which is attached to an outer area of the connection surface (20b) of the actuation part (20) and with a second surface (30b) is attached to an outer area of the connection surface (10a) of the main body (10),
at least one sensor (41, 42, 43, 44), which is located between the main body (10) and the actuation part (20) and viewed in the thickness direction (Z), is located at the side of the connection device (30), so that each sensor (41, 42, 43, 44) can be used to detect a position of one region, arranged on said sensor, of the second surface in the thickness direction (Z).

4. (canceled)

5. Switch device (1), comprising:
a plate-shaped main body (10) with a connection surface (10a), which is facing the actuation side (S1) of the electrical switch device (1),
a plate-shaped actuation part (20) arranged thereon, viewed in the thickness direction (Z), with an actuation surface (20a) facing the actuation side (S1) and a connection surface (20b) located opposite to this,
a display (80) integrated in the actuation part (20) for displaying images on the actuation side (S1), wherein the housing part (H1) comprises: a side wall (H4) extending away from the main body (10), which viewed in the thickness direction (Z) surrounds the actuation part (20) at least in some sections, and an edge section (H5) which adjoins to the side wall (H4) towards the actuation side (S1), which is connected to the actuation part (20) along its circumference at least in some sections and which forms a central opening (H7), in which the display (80) extends, at least in some sections,
at least one sensor (41, 42, 43, 44), which is located between the main body (10) and the actuation part (20) and viewed in the thickness direction (Z), is located at the side of the connection device (30), so that each sensor (41, 42, 43, 44) can be used to detect a position of one region, arranged on said sensor, of the second surface in the thickness direction (Z).

6-28. (canceled)
